(19) United States
(12) Patent Application Publication
(10) Pub. No.: US 2026/0198044 A1
(43) Pub. Date: Jul. 9, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Chen-Han LU, Hsinchu (TW); Yi-Bo LIAO, Hsinchu (TW); Cheng-Ting CHUNG, Hsinchu (TW); Hou-Yu CHEN, Hsinchu (TW); Jin CAI, Hsinchu (TW)

(73) Assignee: Taiwan Semiconductor Manufacturing Company, Ltd., Hsinchu (TW)

(21) Appl. No.: 19/012,418

(22) Filed: Jan. 7, 2025

(51) Int. Cl. H10D 30/00; H10D 30/01

(52) U.S. Cl. CPC H10D 30/508; H10D 30/0191; H10D 30/0196; H10D 30/502

(57) ABSTRACT

A semiconductor structure includes a substrate, a plurality of active channels vertically stacked to each other, a first dielectric layer in the topmost active channel, and a first oxide layer in the topmost active channel and includes a first lateral oxide portion connected with the first dielectric layer. The first lateral oxide portion has a thickness greater than that of the first dielectric layer due to an ox-oxidation.

### BACKGROUND

Gate-All-Around Nanosheet is now the main advanced structure for new generation, as it offers excellent short channel control and increased effective channel width (W_{eff}) per footprint. Reducing the parasitic capacitance of the cell is a key factor for device high-speed driving, which is in highly demand for further generation technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a local portion of a semiconductor structure according to an embodiment of the present disclosure;

FIG. 1_a illustrates a schematic diagram of a cross-sectional view of the local portion of the semiconductor structure in FIG. 1 along a X-Z plane;

FIG. 1_b illustrates a schematic diagram of a cross-sectional view of the local portion of the semiconductor structure in FIG. 1 along a Y-Z plane;

FIG. 2 illustrates a schematic diagram of a local portion of a semiconductor structure according to another embodiment of the present disclosure;

FIG. 2_a illustrates a schematic diagram of a cross-sectional view of a local portion of the semiconductor structure in FIG. 2 along a X-Z plane;

FIG. 2_b illustrates a schematic diagram of a cross-sectional view of the local portion of the semiconductor structure in FIG. 2 along a Y-Z plane;

FIG. 3 illustrates a schematic diagram of a local portion of a semiconductor structure according to another embodiment of the present disclosure;

FIG. 3_a illustrates a schematic diagram of a cross-sectional view of a local portion of a semiconductor structure in FIG. 3 along a X-Z plane;

FIG. 3_b illustrates a schematic diagram of a cross-sectional view of the local portion of the semiconductor structure in FIG. 3 along a Y-Z plane;

FIGS. 4A to 4M illustrate schematic diagrams of manufacturing processes of the semiconductor structure in FIGS. 1_a and 1_b;

FIGS. 5A_a to 5C_b illustrate schematic diagrams of manufacturing processes of the semiconductor structure in FIGS. 2_a and 2_b; and

FIGS. 6A to 6M illustrate schematic diagrams of manufacturing processes of the semiconductor structure in FIGS. 3_a and 3_b.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

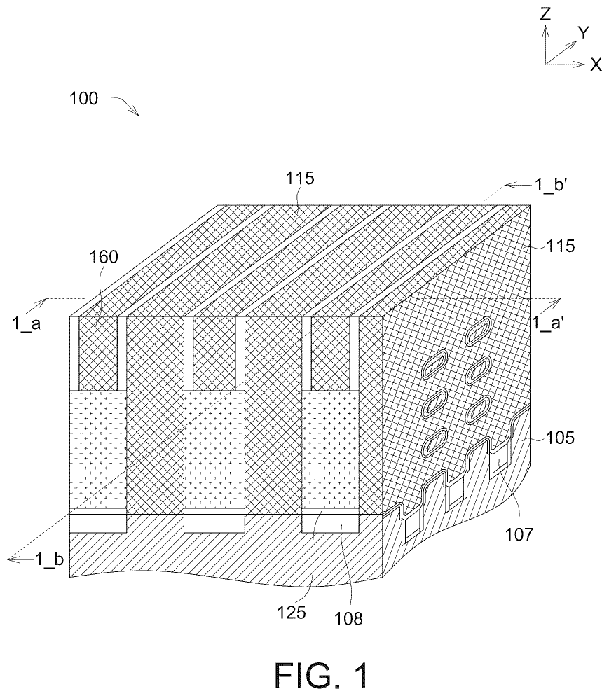

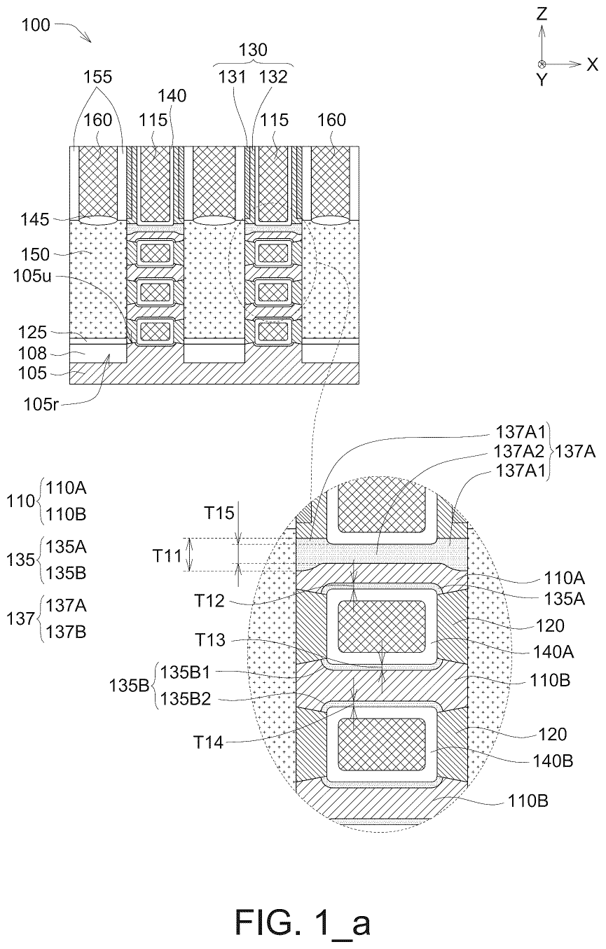

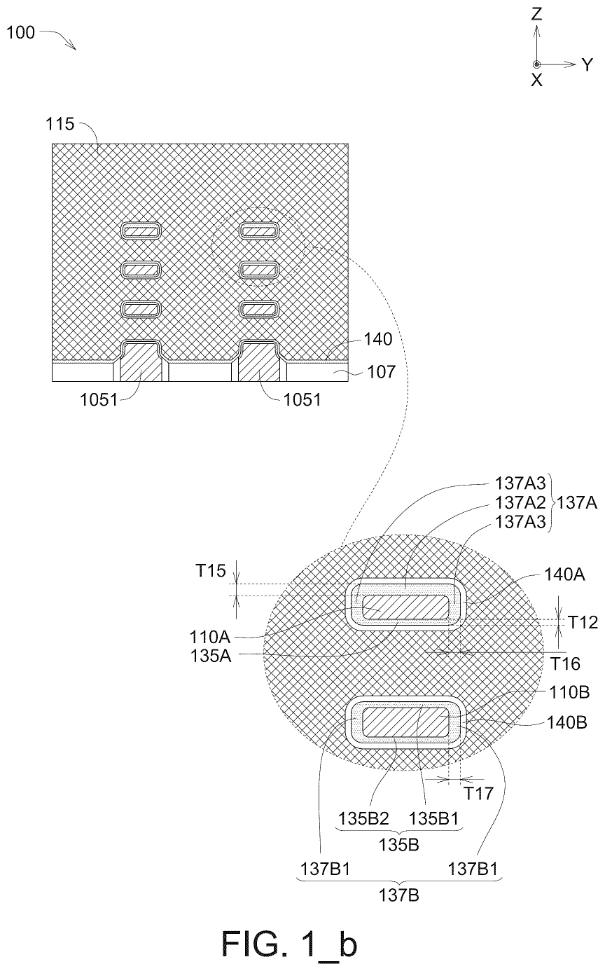

As illustrated in FIGS. 1, 1_a and 1_b, FIG. 1 illustrates a schematic diagram of a local portion of a semiconductor structure 100 according to an embodiment of the present disclosure, FIG. 1_a illustrates a schematic diagram of a cross-sectional view of the local portion of the semiconductor structure 100 in FIG. 1 along a X-Z plane, and FIG. 1_b illustrates a schematic diagram of a cross-sectional view of the local portion of the semiconductor structure 100 in FIG. 1 along a Y-Z plane. The semiconductor structure 100 may include a plurality of transistors having Gate-all-around (GAA) structure or silicon nanosheet structure.

As illustrated in FIGS. 1_a and 1_b, the semiconductor structure 100 includes substrate 105, an oxide layer 107, a plurality of separation layers 108, a plurality of active channels 110, a plurality of metal gates 115, a plurality of inner spacers 120, a plurality of isolation layers 125, a plurality of first spacers (or poly spacer, or gate spacer) 130, a plurality of dielectric layers 135 (for example, a first dielectric layer 135A and a plurality of second dielectric layers 135B), a plurality of oxide layers 137 (for example, a first oxide layer 137A and a plurality of second oxide layers 137B), a plurality of high-k gate dielectric layers 140, a plurality of silicide layer 145, a plurality of source/drain layers 150, a plurality of contact etching stop layers (CESLs) 155, a plurality of contacts 160 and an interlayer dielectric (ILD) 170.

As illustrated in FIG. 1_a, the active channels 110 includes the topmost active channel 110A and a plurality of the active channels 110B, wherein the active channels 110B are located below the topmost active channel 110A. The first dielectric layers 135B are located below the first dielectric layer 135A. The second oxide layers 137B are located below the first oxide layer 137A.

As illustrated in FIG. 1_a, the active channels 110 are vertically stacked to each other in Z-axis. The first dielectric layer 135A is disposed in the topmost active channel 110A. The first oxide layer 137A is disposed in the topmost active channel 110A and includes at least one first lateral oxide portion 137A1 connected with the first dielectric layer 135A. The first lateral oxide portion 137A1 has a thickness T11, the first dielectric layer 135A has a thickness T12, and the thickness T11 of the first lateral oxide portion 137A1 is greater than the thickness T12 of the first dielectric layer 135A due to the re-oxidation for the first oxide layer 137A.

As illustrated in FIG. 1_a, each active channel 110 extends in X-axis (for example, a first direction), the first dielectric layer 135A is disposed in a lower portion of the topmost active channel 110A. The first lateral oxide portion 137A1 has the thickness T11 in Z-axis (for example, a second direction), and the first dielectric layer 135A has the thickness T12 in Z-axis the second direction Z. The Z-axis is substantially perpendicular to X-axis.

As illustrated in FIGS. 1_a to 1_b, the substrate 105 is, for example, a portion of a silicon wafer. The substrate 105 has an upper surface (for example, front surface) 105u and a recess 105r recessed relative to the upper surface 105u. The substrate 105 includes at least one active region (or called an oxide definition (OD) region) 1051. The active region 1051 extends in X-axis.

As illustrated in FIG. 1_b, the oxide layer 107 is formed on a lateral surface of the active regions 1051. In an embodiment, the oxide layer 107 is, for example, a Shallow Trench Isolation (STI) layer.

As illustrated in FIG. 1_a, the active channel 110 may be formed of, for example, silicon. The active channel 110 may be referred to as “nanosheet”. The separation layer 108 is disposed within a wall of the recess 105r. The separation layer 108 may be formed of silicon or insulation material.

As illustrated in FIG. 1_a, the metal gate 115 is disposed on the active channel 110 and between the adjacent two active channels 110. By way of example, the metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the metal gate 115 may be formed by ALD, PVD, CVD, e-beam evaporation, or other suitable process. Further, the metal gate 115 may be formed separately for n-type transistors and p-type transistors, which may use different metal layers (e.g., for providing different n-type and p-type work function metal layers).

As illustrated in FIG. 1_a, the inner spacer 120 is disposed adjacent to a lateral surface of the metal gate 115, a lateral surface of the dielectric layer 135 and/or a lateral surface of the high-k gate dielectric layer 140. The isolation layer 125 is disposed over the separation layer 108. The isolation layer 125 is formed of, for example, an insulation material. The isolation layer 125 may electrically isolate the substrate 110 from the source/drain layer 150.

As illustrated in FIG. 1_a, the first spacer 130 may be a multi-layered structure or a single-layered structure. For the multi-layered structure, the first spacer 130 includes a first-sub spacer portion and a second-sub spacer portion. The second-sub spacer portion is disposed between the metal gate (or the high-k gate dielectric layer 140) and the first-sub spacer portion. In terms of material, the first-sub spacer portion may be formed of one of SiO, SiN, SiOC, SiON, SiOCN, etc., the second-sub spacer portion may be formed of another of SiO, SiN, SiOC, SiON, SiOCN, etc.

In the present embodiment, the first spacer 130 has a high oxygen concentration due to the first spacer 130 being subjected to a re-oxidation process, for example, a plasma, plasma ashing, etc. The oxide layers 137 are formed in the corresponding active channels 110 in the re-oxidation process. Due to the first spacer 130 being re-oxidation layer (having high oxygen concentration), the dielectric constant of the first spacer 130 may be reduced, and accordingly the parasitic capacitance between the components (for example, the contacts 160, the source/drain layers 150, etc.) in adjacent two sides of the oxide layers 137 may be reduced, and the switching speed of the device may be increased. In addition, the oxygen concentration of the first spacers 130 may be detected by EDX (Energy Dispersive X-rayspectroscopy) mapping.

As illustrated in FIG. 1_a, in X-Z plane, the dielectric layers 135 are formed on or in the active channels 110 respectively. Furthermore, each second dielectric layer 135B including an upper dielectric portion 135B1 and a lower dielectric portion 135B2 is formed in the corresponding active channel 110B, wherein the upper dielectric portion 135B1 is formed in an upper portion of the active channel 110B, and the lower dielectric portion 135B2 is formed in a lower portion of the active channel 110B. In the present embodiment, the upper dielectric portion 135B1 has a thickness T13, and the lower dielectric portion 135B2 has a thickness T14, wherein the thickness T13 and the thickness T14 are substantially equal. In an embodiment, the upper dielectric portion 135B1 and the lower dielectric portion 135B2 are not subjected to the re-oxidation process. In an embodiment, the thickness T12, the thickness T13 and the thickness T14 are substantially equal. In addition, the dielectric layer 135 is, for example, an interface layer (IL). The dielectric layer 135 may be deposited by any appropriate method, such as ALD, CVD, and/or PVD. The dielectric layer 135 may include silicon oxide (SiO2), or silicon oxynitride (SiON).

As illustrated in FIG. 1_a, in X-Z plane, the first oxide layer 137A further includes a first upper oxide portion 137A2 disposed in an upper portion of the topmost active channel 110A and has a thickness T15 in Z-axis. The thickness T15 of the first upper oxide portion 137A2 is greater than the thickness T12 of the first dielectric layer 135A due to the re-oxidation for the first upper oxide portion 137A2.

As illustrated in FIG. 1_b, in Y-Z plane, the first oxide layer 137A further includes a plurality of second lateral oxide portion 137A3. The second lateral oxide portions 137A3 are formed in adjacent two lateral portions of the topmost active channel 110A. The second lateral oxide portion 137A3 is connected with the topmost dielectric layer 135A. The second upper oxide portion 137A3 has a thickness T16 in Y-axis (for example, a third direction). The thickness T16 of the second upper oxide portion 137A3 is greater than the thickness T12 of the first dielectric layers 135A due to the re-oxidation for the second upper oxide portion 137A3 (the lateral action of the plasma). In addition, the thickness T15 of the first upper oxide portion 137A2 may be greater than the thickness T16 of the second lateral oxide portion 137A3 due to the re-oxidation for the first upper oxide portion 137A2 (the vertical action of the plasma) being stronger than that of the second lateral oxide portion 137A3 (the lateral action of the plasma).

As illustrated in FIG. 1_b, in Y-Z plane, the second oxide layer 137B includes a plurality of lateral oxide portions 137B1. The lateral oxide portions 137B1 are formed in lateral portions of the corresponding active channel 110B. The lateral oxide portion 137B1 has a thickness T17 in Y-axis, wherein the thickness T17 of the lateral oxide portion 137B1 is greater than the thickness T12 or the thickness T13 due to the re-oxidation for the second oxide layer 137B (the lateral action of the plasma).

As illustrated in FIG. 1_a, a high-k gate dielectric layer 140A of the high-k gate dielectric layers 140 disposed on the first dielectric layers 135A, the corresponding second dielectric layer 135B and the topmost inner spacer 120 is formed by using, for example, deposition. A high-k gate dielectric layer 140B of the high-k gate dielectric layers 140 disposed on the corresponding second dielectric layer 135B and the corresponding inner spacer 120 is formed by using, for example, deposition. The high-k gate dielectric layer 140A and the high-k gate dielectric layer 140B may be formed in the same process, for example, deposition, such as ALD, CVD, metal-organic CVD, PVD, or a combination thereof.

The high-k gate dielectric layer 140 may be formed of a material including: (i) a high-k dielectric material, such as hafnium oxide (HfO₂), titanium oxide (TiO₂), hafnium zirconium oxide (HfZrO), tantalum oxide (Ta2O3), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor structure structures and manufacturing processes, high-k refers to a dielectric constant that is greater than the dielectric constant of SiO₂ (e.g., greater than 3.9).

As illustrated in FIGS. 1_a and 1_b, the silicide layers 145 are formed over the exposed source/drain layers 150. The source/drain layer 150 may be formed over the isolation layer 125 and the active channels 110. The source/drain layer 150 may be a source region or a drain region of a transistor, wherein the transistor is, for example, N-type transistor or P-type transistor. In some embodiments, the forming of the silicide layers 145 includes annealing to induce a chemical interaction between the conductive materials of the contact 160 and the source/drain layer 150.

As illustrated in FIGS. 1_a and 1_b, the CESL 155 is formed over the source/drain layer 150 and the first spacer 130. The contact 160 is formed over the silicide layer 145, the CESL 155 and the source/drain layer 150. The source/drain layer 150 may be formed using an epitaxial process, such as VPE, UHV-CVD, MBE, and/or other suitable processes. Example n-type source/drain layer may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain layer may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process). The first spacer 130 may include a first-sub spacer portion 131 and a second-sub spacer portion 132, wherein the second-sub spacer portion 132 is disposed between a top portion of the metal gate 115 and the first-sub spacer portion 131. In an embodiment, the first-sub spacer portion 131 may be formed of a material different from that of the second-sub spacer portion 132. The first-sub spacer portion 131 may be formed of one of SiO, SiN, SiOC, SiON, SiOCN, etc., the second-sub spacer portion 132 may be formed of another of SiO, SiN, SiOC, SiON, SiOCN, etc. In addition, the first spacer 130 may be formed by using, for example, SACVD (Sub-Atmospheric CVD), FCCVD (Flowable CVD), ALD, PVD or other suitable process.

As illustrated in FIG. 1_a, the contacts 160 may be formed of a metal including the material the same as or similar to that of the metal gate 115. The ILD 170 is formed over the CESL 155 and has a plurality of holes exposing the silicide layers 145. The contacts 160 are formed within the holes of the ILD 170.

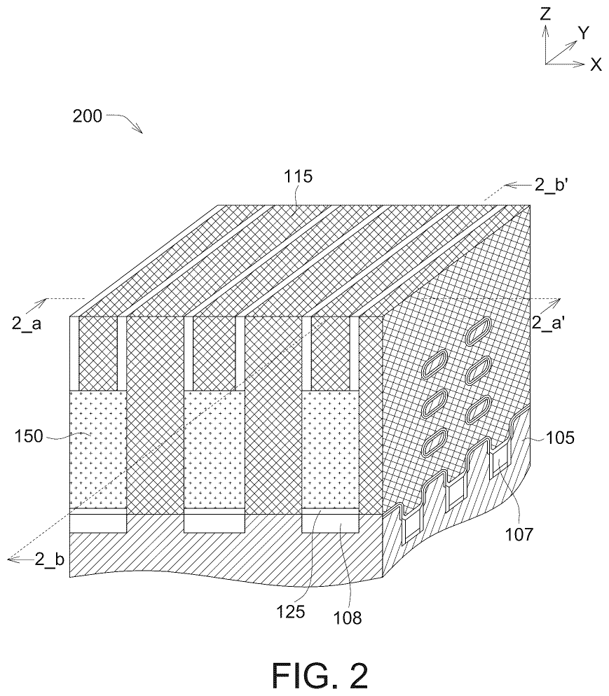

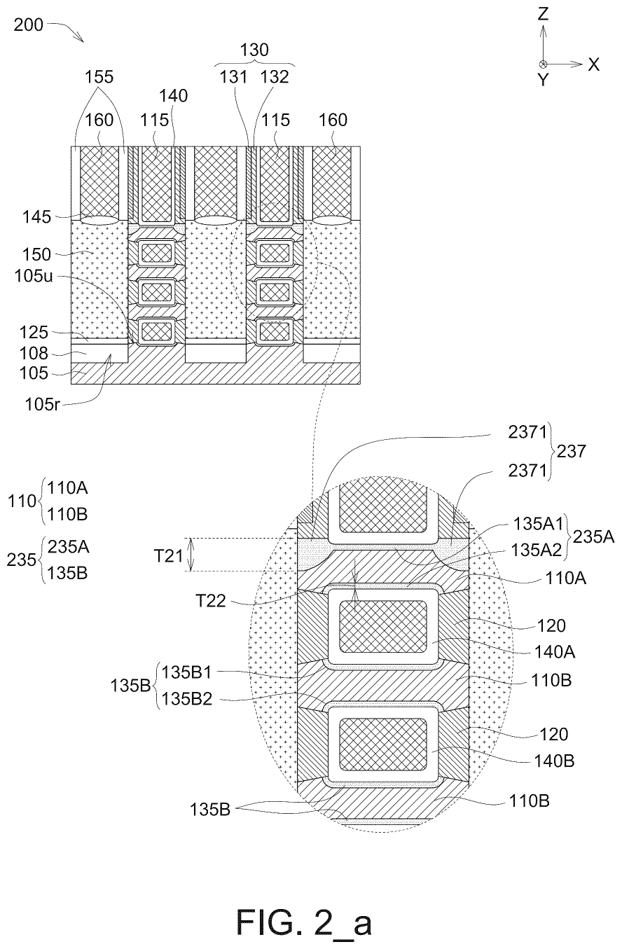

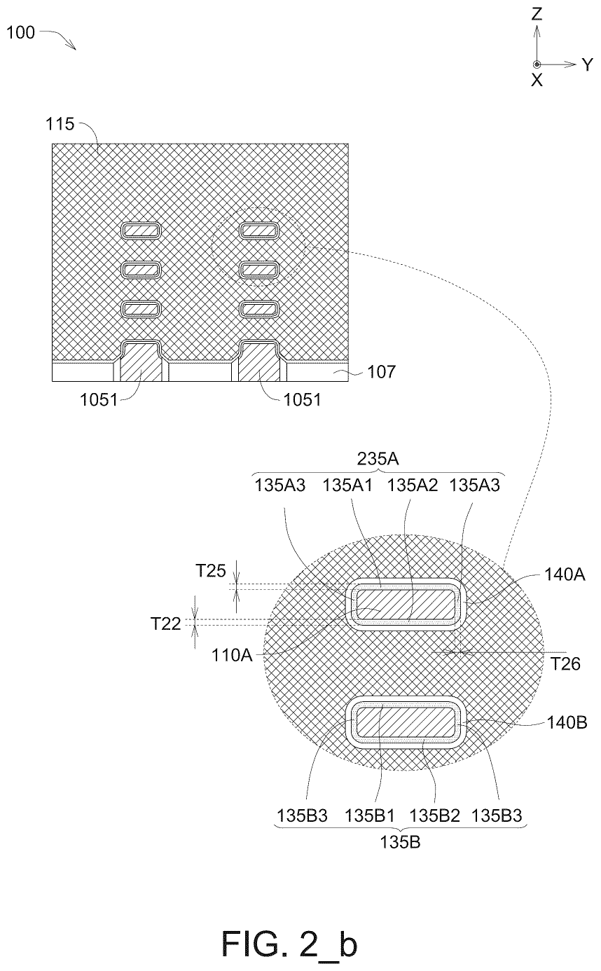

As illustrated in FIGS. 2, 2_a and 2_b, FIG. 2 illustrates a schematic diagram of a local portion of a semiconductor structure 200 according to another embodiment of the present disclosure, FIG. 2_a illustrates a schematic diagram of a cross-sectional view of a local portion of the semiconductor structure 200 in FIG. 2 along a X-Z plane, and FIG. 2_b illustrates a schematic diagram of a cross-sectional view of the local portion of the semiconductor structure 200 in FIG. 2 along a Y-Z plane. The semiconductor structure 200 may include a plurality of transistors having Gate-all-around (GAA) structure or silicon nanosheet structure.

As illustrated in FIGS. 2_a and 2_b, the semiconductor structure 200 includes the substrate 105, the oxide layer 107, a plurality of the separation layers 108, a plurality of the active channels 110, a plurality of the metal gates 115, a plurality of the inner spacers 120, a plurality of the isolation layers 125, a plurality of the first spacers 130, a plurality of the first dielectric layers 235 (for example, a first dielectric layer 235A and a plurality of the dielectric layers 135B), a first oxide layer 237, a plurality of the high-k gate dielectric layers 140, a plurality of the silicide layers 145, a plurality of the source/drain layers 150, a plurality of the contact etching stop layers 155, a plurality of the contacts 160 and the interlayer dielectric 170.

As illustrated in FIG. 2_a, the active channels 110 includes the topmost active channel 110A and a plurality of the active channels 110B, wherein the active channels 110B are located below the topmost active channel 110A. The second dielectric layers 135B are located below the first dielectric layer 235A.

As illustrated in FIG. 2_a, the active channels 110 are vertically stacked to each other in Z-axis. The first dielectric layer 235A is disposed in the topmost active channel 110A. The first oxide layer 237 is disposed in the topmost active channel 110A and includes a plurality of lateral oxide portions 2371 connected with the first dielectric layer 235A. The lateral oxide portion 2371 has a thickness T21, the first dielectric layer 235A has a thickness T22, and the thickness T21 of the lateral oxide portion 2371 is greater than the thickness T22 of the first dielectric layer 235A due to the re-oxidation for the first oxide layer 237.

As illustrated in FIG. 2_a, in X-Z plane, each active channel 110 extends in X-axis, the first dielectric layer 235A includes an upper dielectric portion 135A1 and a lower dielectric portion 135A2, wherein the upper dielectric portion 135A1 is disposed in an upper portion of the topmost active channel 110A, and the lower dielectric portion 135A2 is disposed in a lower upper portion of the topmost active channel 110A. The lateral oxide portion 2371 has the thickness T21 in Z-axis, and the first dielectric layer 235A has the thickness T22 in Z-axis. The lower dielectric portion 135A2 has the structure the same as or similar to that of the first dielectric layer 135A in FIG. 1_a.

As illustrated in FIG. 2_b, in Y-Z plane, the first dielectric layer 235A further includes at least one lateral dielectric portion 135A3. The lateral dielectric portions 135A3 are formed in adjacent two lateral portions of the topmost active channel 110A. The lateral dielectric portions 235A is connected with the high-k gate dielectric layer 140. The upper dielectric portion 135A1 has a thickness T25 in Z-axis, the lower dielectric portion 135A2 of the first dielectric layer 235A has the thickness T22 in Z-axis, and the lateral dielectric portion 135A3 has a thickness T26 in Y-axis, wherein the thickness T25 of the upper dielectric portion 135A1,the thickness T22 of the lower dielectric portion 135A2 and the thickness T26 of the lateral dielectric portion 135A3 may be substantially equal due to the blocking of the barrier layer (for example, a BARC) in manufacturing processes for the semiconductor structure 200.

As illustrated in FIG. 2_b, in Y-Z plane, the second dielectric layer 135B may include the feature the same as or similar to that of the first dielectric layer 235A. Furthermore, the second dielectric layer 135B includes the upper dielectric portion 135B1 a lower dielectric portion 135B2 and at least one lateral dielectric portion 135B3, wherein the upper dielectric portion 135B1 is disposed in the upper portion of the corresponding active channel 110B, the lower dielectric portion 135B2 is disposed in the lower upper portion of the corresponding active channel 110B, and the lateral dielectric portions 135B3 are disposed in the lateral portions of the corresponding active channel 110B. The upper dielectric portion 135B1 has a thickness equal to the thickness T25 of the upper dielectric portion 135A1, the lower dielectric portion 135B2 has a thickness equal to the thickness T22 of the lower dielectric portion 135A2, and the lateral dielectric portion 135B3 has a thickness equal to the thickness T26 of the lateral dielectric portion 135A3.

In addition, the dielectric layer 235 including the first dielectric layer 235A and the second dielectric layers 135B is, for example, an interface layer (IL). The dielectric layer 235 may be deposited by any appropriate method, such as ALD, CVD, and/or PVD. The dielectric layer 235 may include silicon oxide (SiO2), or silicon oxynitride (SiON).

As illustrated in FIGS. 2_a to 2_b, the substrate 105 is, for example, a portion of a silicon wafer. The substrate 105 has the upper surface (for example, front surface) 105u and the recess 105r recessed relative to the upper surface 105u. The substrate 105 includes at least one active region (or called an oxide definition (OD) region) 1051. The active region 1051 extends in X-axis.

As illustrated in FIG. 2_b, the oxide layer 107 is formed on a lateral surface of the active regions 1051. In an embodiment, the oxide layer 107 is, for example, a Shallow Trench Isolation (STI) layer.

As illustrated in FIG. 2_a, the active channel 110 may be formed of, for example, silicon. The active channel 110 may be referred to as “nanosheet”. The separation layer 108 is disposed within a wall of the recess 105r.

As illustrated in FIG. 2_a, the metal gate 115 is disposed on the active channel 110 and between the adjacent two active channels 110. By way of example, the metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the metal gate 115 may be formed by ALD, PVD, CVD, e-beam evaporation, or other suitable process. Further, the metal gate 115 may be formed separately for n-type transistors and p-type transistors, which may use different metal layers (e.g., for providing different n-type and p-type work function metal layers).

As illustrated in FIG. 2_a, the inner spacer 120 is disposed adjacent to a lateral surface of the metal gate 115, a lateral surface of the dielectric layer 235 and/or a lateral surface of the high-k gate dielectric layer 140. The isolation layer 125 is disposed over the separation layer 108. The isolation layer 125 is formed of, for example, an insulation material. The isolation layer 125 may electrically isolate the substrate 110 from the source/drain layer 150.

As illustrated in FIG. 2_a, the first spacer 130 may be a multi-layered structure or a single-layered structure. For the multi-layered structure, the first spacer 130 includes a first-sub spacer portion and a second-sub spacer portion. The second-sub spacer portion is disposed between the metal gate and the first-sub spacer portion. In terms of material, the first-sub spacer portion may be formed of one of SiO, SiN, SiOC, SiON, SiOCN, etc., the second-sub spacer portion may be formed of another of SiO, SiN, SiOC, SiON, SiOCN, etc.

In the present embodiment, the first spacer 130 has the high oxygen concentration due to the first spacer 130 being subjected to a re-oxidation process, for example, a plasma, plasma ashing, etc. The first oxide layers 237 are formed in the corresponding active channels 110 in the re-oxidation process. Due to the first spacer 130 being re-oxidation layer (having high oxygen concentration), the dielectric constant of the first spacer 130 may be reduced, and accordingly the parasitic capacitance between the components (for example, the contacts 160, the source/drain layers 150, etc.) in adjacent two sides of the oxide layers 137 may be reduced, and the switching speed of the device may be increased. In addition, the oxygen concentration of the first spacers 130 may be detected by EDX (Energy Dispersive X-rayspectroscopy) mapping.

As illustrated in FIG. 2_a, the high-k gate dielectric layer 140A disposed on the first dielectric layers 235A, the corresponding second dielectric layer 135B and the topmost inner spacer 120 is formed by using, for example, deposition. The high-k gate dielectric layer 140B disposed on the corresponding second dielectric layer 135B and the corresponding inner spacer 120 is formed by using, for example, deposition. The high-k gate dielectric layer 140A and the high-k gate dielectric layer 140B may be formed in the same process, for example, deposition, such as ALD, CVD, metal-organic CVD, PVD, or a combination thereof.

As illustrated in FIGS. 2_a and 2_b, the silicide layer 145 are formed over the exposed epitaxies 150. The source/drain layer 150 may be formed over the isolation layer 125 and the active channels 110. The source/drain layer 150 may be a source region or a drain region of a transistor, wherein the transistor is, for example, N-type transistor or P-type transistor. In some embodiments, the forming of the silicide layer 145 includes annealing to induce a chemical interaction between the conductive materials of the contact 160 and the source/drain layer 150.

As illustrated in FIGS. 2_a and 2_b, the CESL 155 is formed over the source/drain layer 150 and the first spacer 130. The contact 160 is formed over the silicide layer 145, the CESL 155 and the source/drain layer 150. The source/drain layer 150 may be formed using an epitaxial process, such as VPE, UHV-CVD, MBE, and/or other suitable processes. Example n-type source/drain layer may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain layer may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process).

As illustrated in FIG. 2_a, the contacts 160 may be formed of a metal including Ru, Mo, Co, Ni, W, Ti, Ta, Cu, Al, TiN, TaN or a combination thereof. The contact 160 may be formed by any suitable process, such as PVD, CVD, ALD, electroplating, or other suitable methods. The ILD 170 is formed over the CESL 155 and has a plurality of holes exposing the silicide layers 145. The contacts 160 are formed within the holes of the ILD 170.

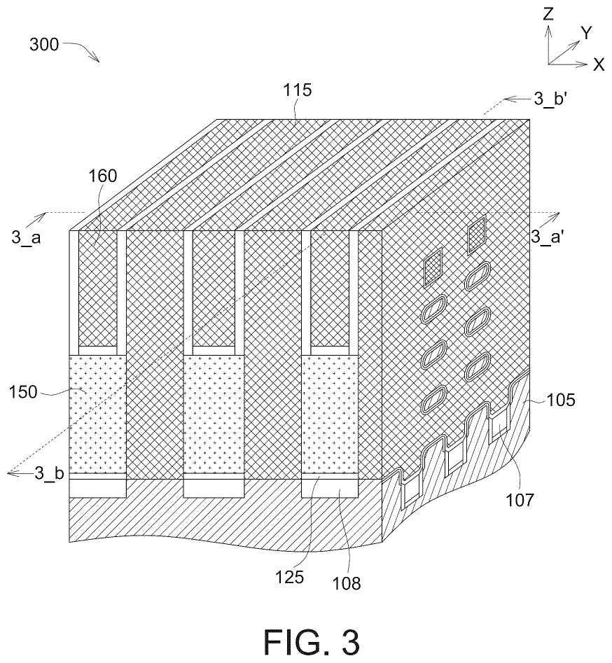

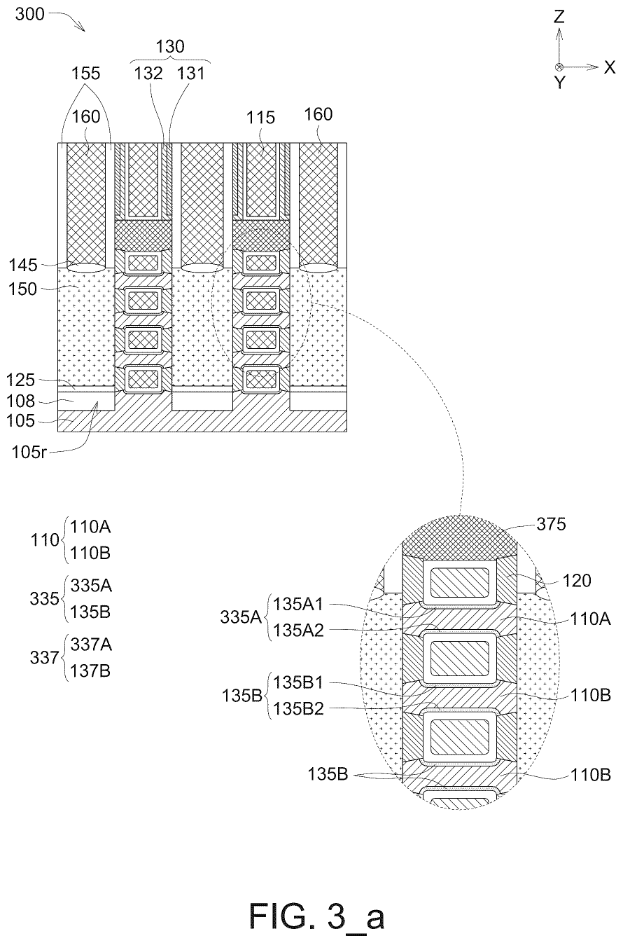

As illustrated in FIGS. 3, 3_a and 3_b, FIG. 3 illustrates a schematic diagram of a local portion of a semiconductor structure 300 according to another embodiment of the present disclosure, FIG. 3_a illustrates a schematic diagram of a cross-sectional view of a local portion of a semiconductor structure 300 in FIG. 3 along a X-Z plane, and FIG. 3_b illustrates a schematic diagram of a cross-sectional view of the local portion of the semiconductor structure 300 in FIG. 3 along a Y-Z plane. The semiconductor structure 300 may include a plurality of transistors having Gate-all-around (GAA) structure or silicon nanosheet structure.

As illustrated in FIGS. 3_a and 3_b, the semiconductor structure 300 includes the substrate 105, the oxide layer 107, a plurality of the separation layers 108, a plurality of the active channels 110, a plurality of the metal gates 115, a plurality of the inner spacers 120, a plurality of the isolation layers 125, a plurality of the first spacers 130, a plurality of the dielectric layers 335 (for example, a first dielectric layer 335A and a plurality of the second dielectric layers 135B), a plurality of oxide layers 337 (for example, a first oxide layer 337A and a plurality of second oxide layers 137B), a plurality of the high-k gate dielectric layers 140, a plurality of the silicide layers 145, a plurality of the source/drain layers 150, a plurality of the contact etching stop layers (CESLs) 155, a plurality of the contacts 160, the interlayer dielectric (ILD) 170 and a plurality of blocking layers 375.

As illustrated in FIG. 3_a, the active channels 110 includes the topmost active channel 110A and a plurality of the active channels 110B, wherein the active channels 110B are located below the topmost active channel 110A. The second dielectric layers 135B are located below the first dielectric layer 135A. The second oxide layers 137B are located below the first oxide layer 337A.

As illustrated in FIGS. 3_a and 3_b, the active channels 110 are vertically stacked to each other in Z-axis. The first dielectric layer 335A is disposed in the topmost active channel 110A. The first oxide layer 337A is disposed in the topmost active channel 110A and includes at least one second lateral oxide portion 137A3 connected with the first dielectric layer 335A. The second lateral oxide portion 137A3 has the thickness T16 in Y-axis. The first dielectric layer 335A includes an upper dielectric portion 135A1 and a lower dielectric portion 135A2, wherein the upper dielectric portion 135A1 and the lower dielectric portion 135A2 may have substantially equal thicknesses. The lower dielectric portion 135A2 has the thickness T12 in Z-axis, and the thickness T16 of the second lateral oxide portion 137A3 is greater than the thickness T12 of the lower dielectric portion 135A2 (and/or that of the upper dielectric portion 135A1) due to the re-oxidation for the second lateral oxide portion 137A3.

As illustrated in FIG. 3_b, the second oxide layer 137B is disposed in the corresponding active channel 110B and includes at least one lateral oxide portion 137B1. The lateral oxide portion 137B1 has the thickness T17 in X-axis. The second dielectric layer 135B is disposed in the corresponding active channel 110B and includes the upper dielectric portion 135B1 and the lower dielectric portion 135B 2. The upper dielectric portion 135B1 is formed in the upper portion of the corresponding active channel 110B, and the lower dielectric portion 135B2 is formed in the lower portion of the corresponding active channel 110B. The upper dielectric portion 135B1 has the thickness T13 in Z-axis, and the lower dielectric portion 135B2 has the thickness T14 in Z-axis, wherein the thickness T13 and the thickness T14 are substantially equal. In an embodiment, the thickness T12, the thickness T13 and the thickness T14 are substantially equal. The lateral oxide portion 137B1 has the thickness T17 in X-axis. The thickness T17 of the lateral oxide portion 137B1 is greater than the thickness T13 of the upper dielectric portion 135B1 and the thickness T14 of the lower dielectric portion 135B2 due to the re-oxidation for the second oxide layer 137B.

As illustrated in FIGS. 3_a and 3_b, each blocking layer 375 is disposed over the corresponding topmost active channel 110A. The blocking layer 375 is surrounded by a high-k gate dielectric layer 140C of the high-k gate dielectric layers 140. Due to the blocking of the blocking layer 375, the upper dielectric portion 135A1 of the first dielectric layer 335A may not be subjected to the re-oxidation during the plasma process. In addition, the blocking layer 375 may be formed of a material including, for example, silicon nitride, silicon oxynitride, or the like.

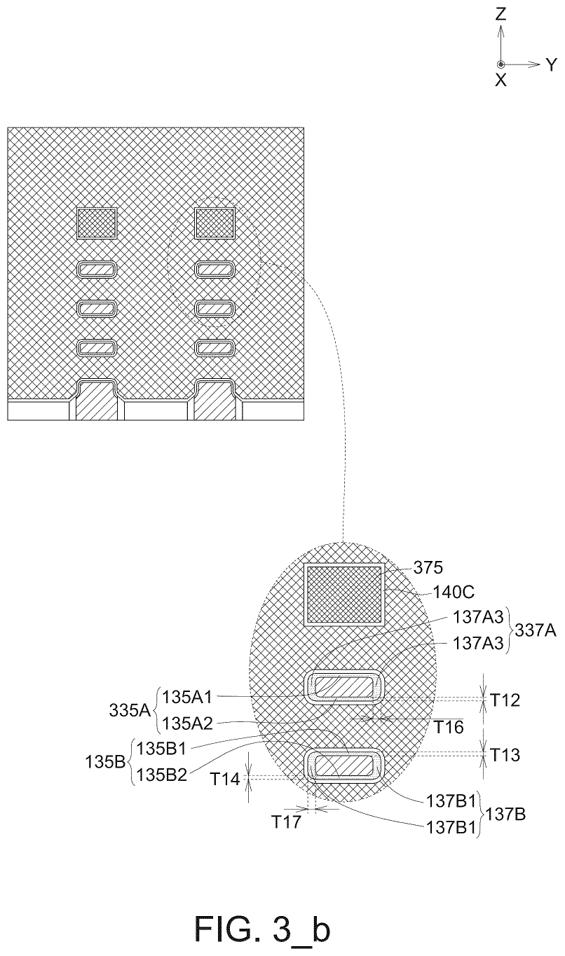

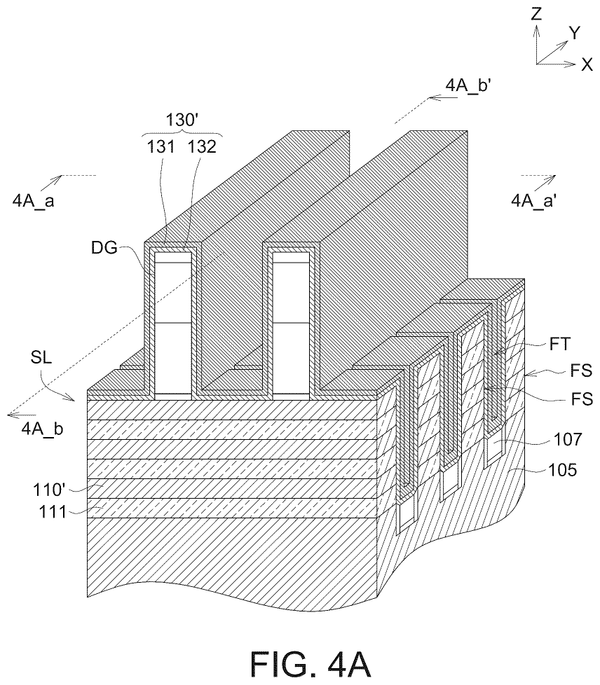

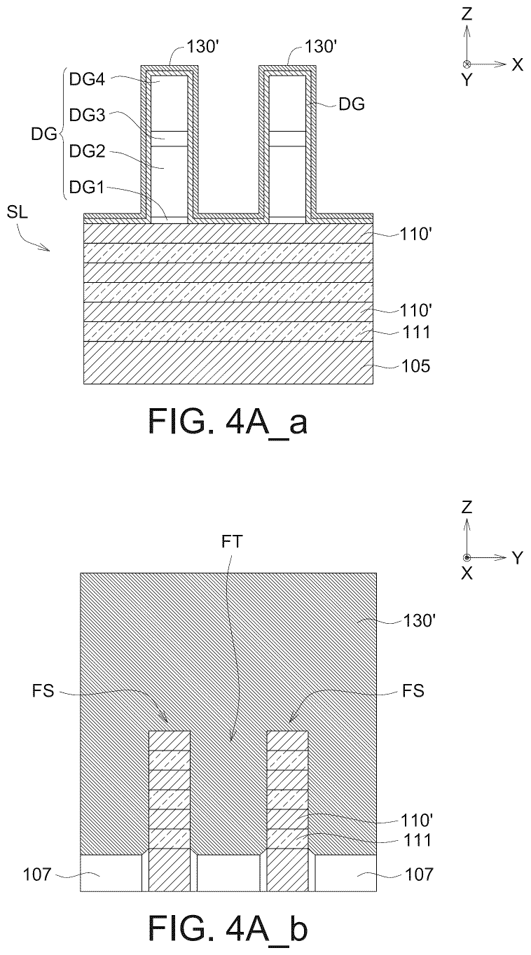

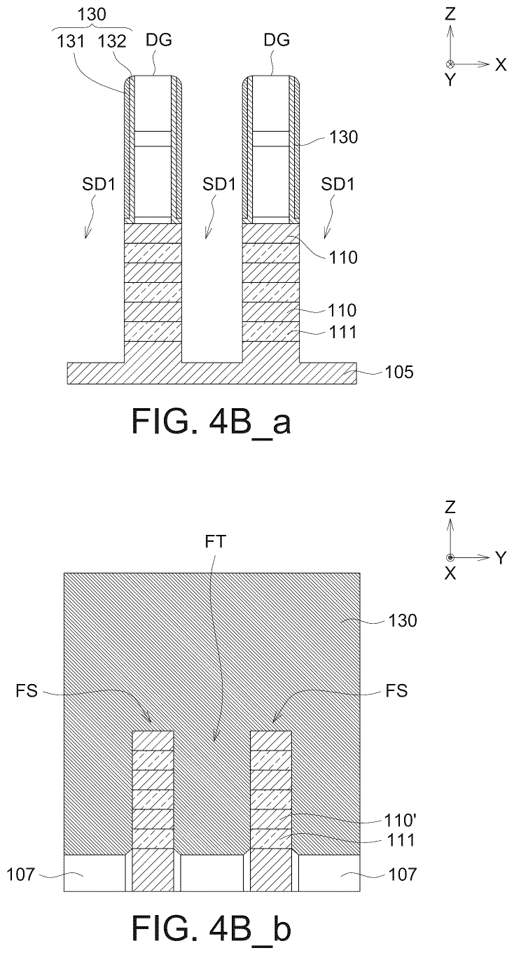

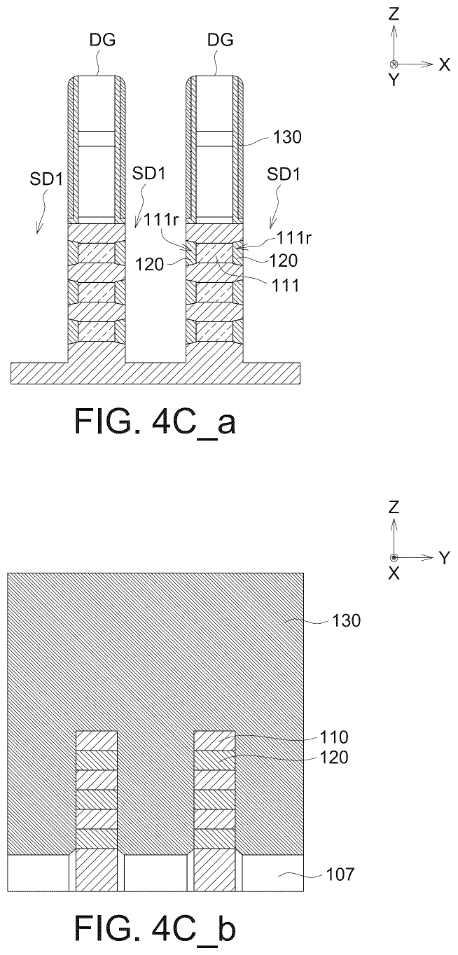

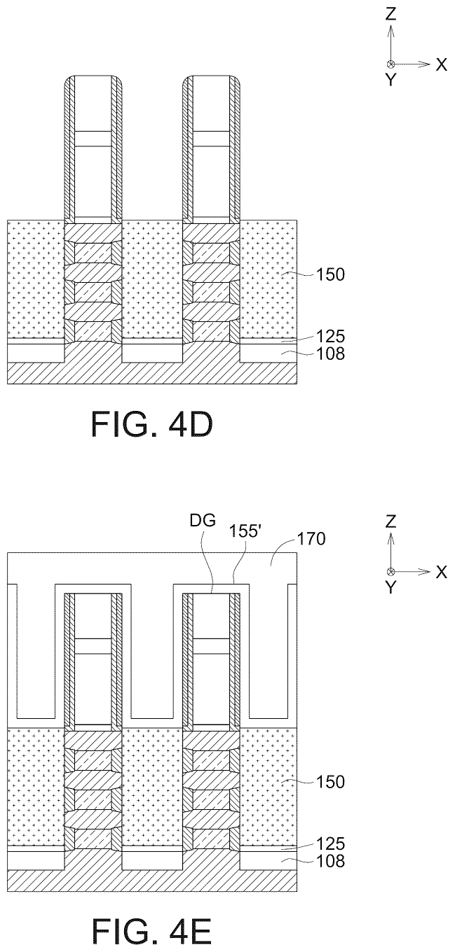

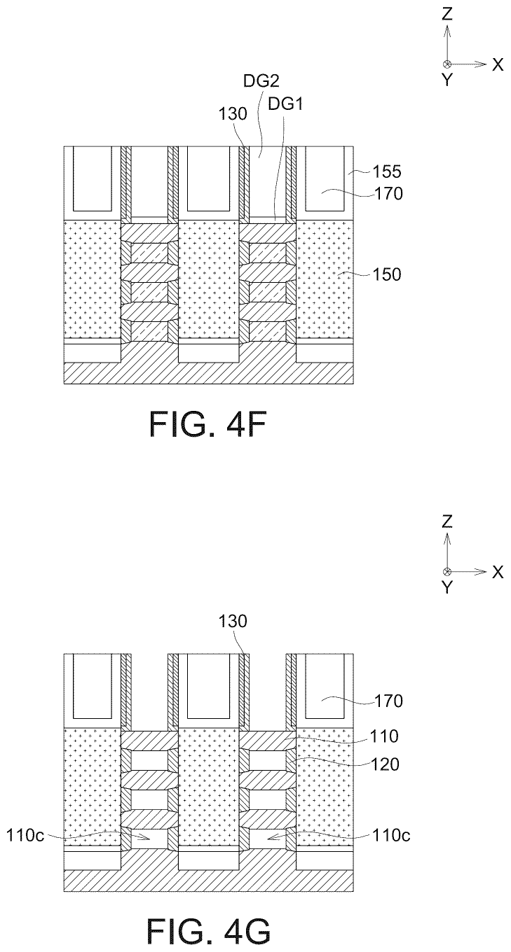

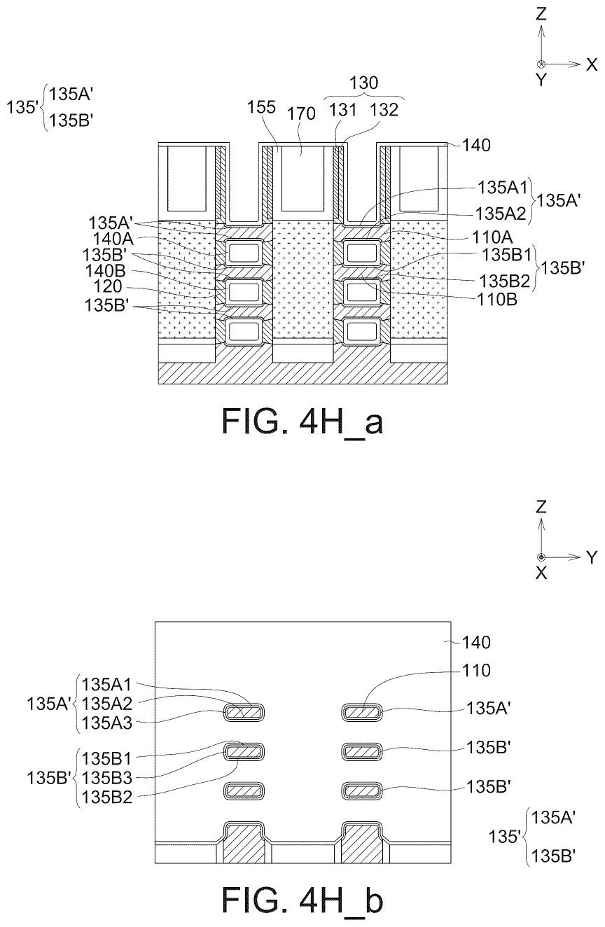

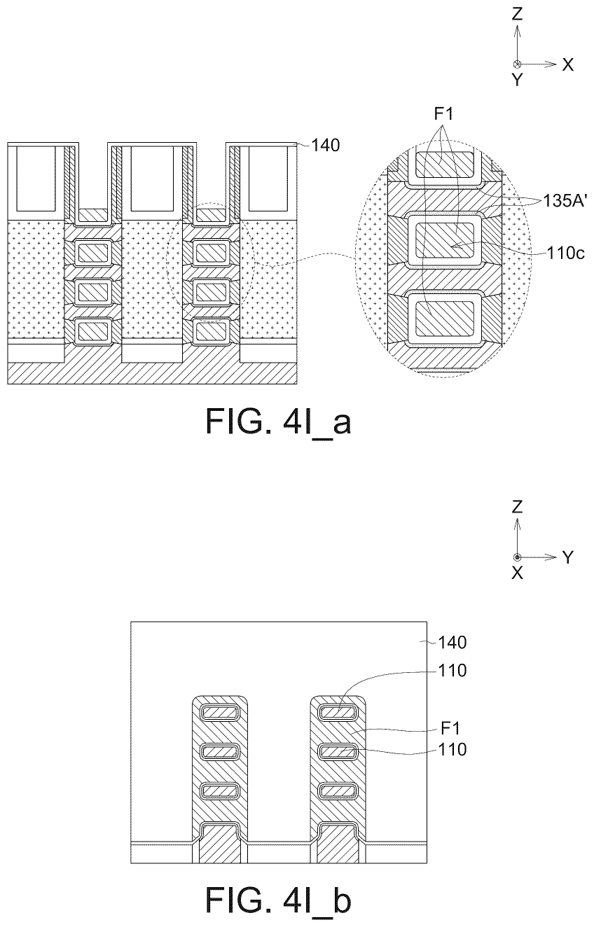

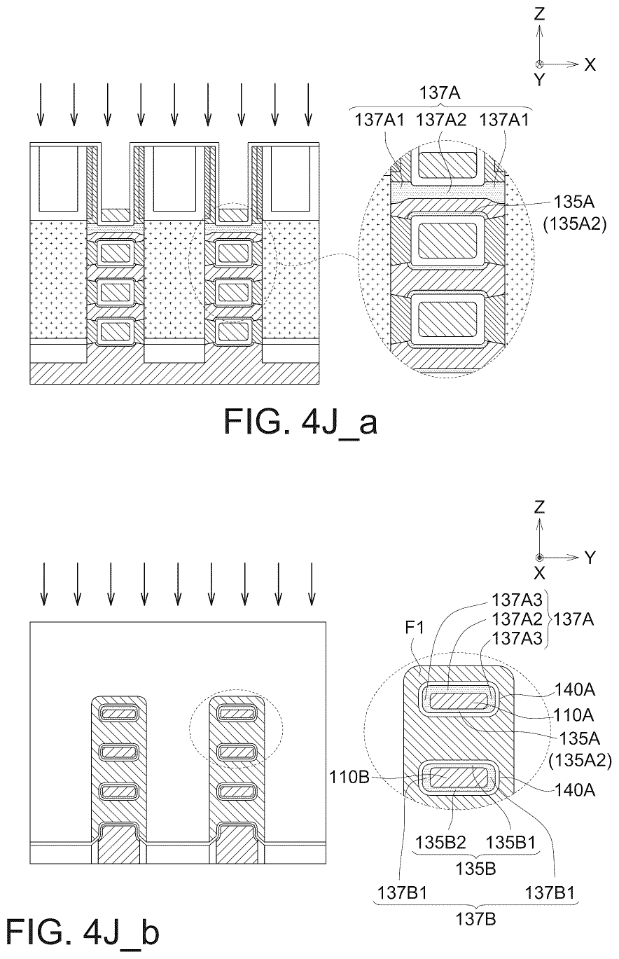

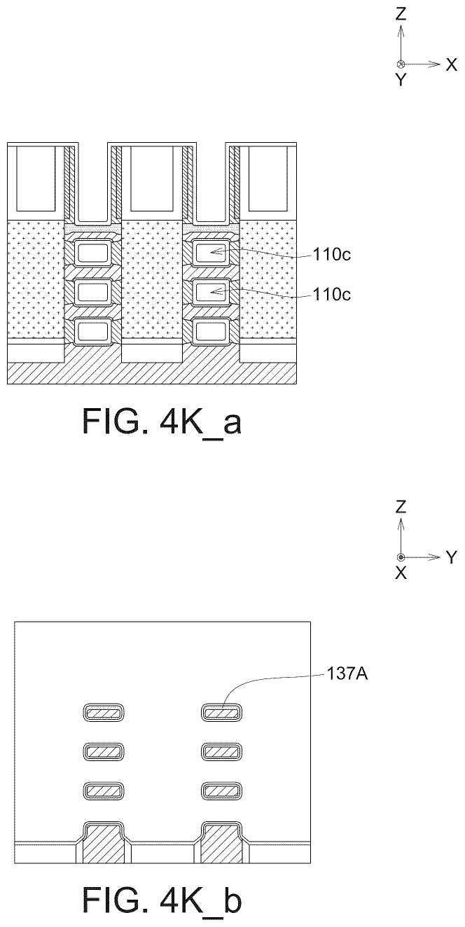

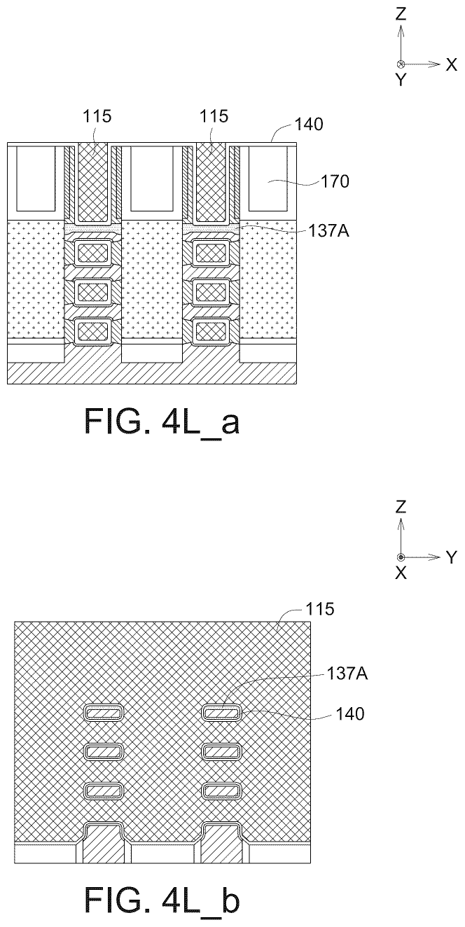

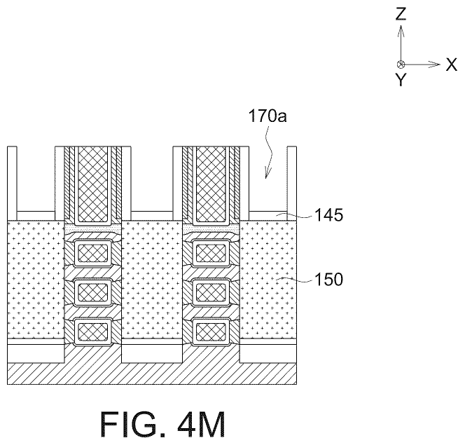

FIGS. 4A to 4M illustrate schematic diagrams of manufacturing processes of the semiconductor structure 100 in FIGS. 1_a and 1_b.

As illustrated in FIGS. 4A, 4_a and 4_b, a superlattice structure SL including a plurality of silicon germanium (SiGe) layers 111 and a plurality of silicon layers 110′ is formed on the substrate 105 by epitaxy process, for example, molecular beam epitaxy (MBE), metalorganic chemical vapor deposition (MOCVD) or other suitable epitaxial growth processes. One of the silicon germanium layers 111 is disposed between adjacent two of the silicon layers 110′. The substrate 105 is, for example, silicon wafer. The superlattice structure SL may be patterned to form a plurality of fin structures (or referred to as “OD (oxide diffusion)”) FS by using, for example, deposition, photolithography, etching, etc. After patterned, each fin structure FS includes the patterned SiGe layers 111 and silicon layers 110′, and a fin trench FT is formed adjacent two of the fin structures FS. Then, an oxide layer 107 may be formed in a bottom portion of the fin trench FT between adjacent two of the fin structures FS. The oxide layer 107 may be formed of a material including silicon oxide, silicon nitride, silicon carbide, FSG (fluorosilicate glass), low dielectric constant material or other suitable dielectric material. The dielectric material may be formed in the fin trench FT between adjacent two of the fin structures FS by using, for example, deposition such as hot growth, CVD (Chemical Vapor Deposition), HDP-CVD (High-density plasma CVD), PVD (Physical Vapor Deposition), ALD (Atomic Layer Deposition) and/or spin coating. Then, the dielectric material is planarized by, for example, a CMP (Chemical-Mechanical Planarization) to expose the topmost silicon layer 110′. Then, a portion of the dielectric material is removed by, for example, dry etching, wet etching, RIE (Reactive-Ion Etching) or other etching process, and the remaining portion of the dielectric material forms the oxide layers 107. The oxide layer 107 is referred to as, for example, a STI (Shallow Trench Isolation).

Then, as illustrated in FIGS. 4A, 4_a and 4_b, a plurality of dummy gate structures DG is formed on the fin structures FS and within the fin trenches FT for defining a region of the active channel, and then a first spacer material 130′ over the dummy gate structures DG and the patterned superlattice structure SL is formed.

The dummy gate structure DG includes a dummy dielectric layer DG1, a dummy gate layer DG2, a mask layer DG3 and an oxide layer DG4. The dummy dielectric layer DG1 is formed on the fin structures FS. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

The first spacer material 130′ may be formed of a material including, for example, SiO, SiN, SiOC, SiON, SiOCN, etc. The first spacer material 130′ may be single-layered structure or a multi-layered structure. For multi-layered structure, the first spacer material 130′ may include a first-sub spacer portion and a second-sub spacer portion, wherein the second-sub spacer portion is disposed between the dummy gate structures DG and the first-sub spacer portion.

As illustrated in FIGS. 4B_a and 4B_b, a portion of the fin structure FS which is not covered by the dummy gate structure DG is removed to form a plurality of source/drain trenches SD1 and a portion of the first spacer material 130′ is removed by etching such as dry etching, wet etching, RIE or other suitable etching process. In addition, the etching process may use bromine-containing etchants (HBr and/or CHBr₃), fluorine-containing etchants (CF₄, SF₆, CH₂F₂, CHF₃ and/or C₂F₆) or other suitable etchant. After etching, the remaining portion of the fin structure FS form a plurality of the active channels 110 and a plurality of the SiGe layers 111 which arranged alternately. After etching, the remaining portion of the first spacer material 130′ forms a plurality of the first spacers 130 which are disposed over the remaining portion of the fin structure FS, for example, the topmost active channels 110.

As illustrated in FIGS. 4C_a and 4C_b, a, two recesses 111r are formed in adjacent two ends of the corresponding SiGe layer 111 by using, for example, wet etching. The wet etching may selectively etches the SiGe layer 111, and the wet etchant includes, but not limited to, ammonium hydroxide (NH₄OH), tetramethylammonium hydroxide (TMAH), ethylenediamine ptrocatechol (EDP) and potassium hydroxide (KOH).

Then, a plurality of the inner spacers 120 are formed in the recesses 111r. In an embodiment, an inner spacer material over the first spacers 130, the active channel 110, the recesses 111r, sidewalls of the source/drain trenches SD1 is formed by using, for example, deposition. The inner spacer material is formed of a material including silicon oxide, silicon nitride, silicon carbide, silicon carbon nitride, silicon carbon nitride, silicon carbon oxynitride or other suitable material. Then, a portion of the inner spacer material is removed by using, for example, ALD, etc. The remaining portion of the inner spacer material forms a plurality of the inner spacers 120.

As illustrated in FIG. 4D, the separation layers 108 may be formed on a bottom the source/drain trenches SD1. In an embodiment, the separation layers 108 may be a semiconductor layer, for example, undoped silicon layer, silicon layer, silicon germanium layer, and the separation layers 108 may be formed by MBE, CVD, MOCVD, etc. Then, the isolation layer 125 over the separation layers 108 is formed by using, for example, deposition, exposure, etching, development, etc. Then, a plurality of the source/drain layers 150 over the isolation layer 125 may be formed within the source/drain trenches SD1.

The source/drain layer 150 may be formed using an epitaxial process, such as VPE, UHV-CVD, MBE, and/or other suitable processes. Example n-type source/drain layer may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain layer may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process).

As illustrated in FIG. 4E, a CESL material 155′ over the first spacers 130, the source/drain layers 150 and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like. Then, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIG. 4F, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the first spacer 130 and the ILD 170 may form, for example, a planarized surface.

As illustrated in FIG. 4G, the SiGe layers 111 and the dummy dielectric layer DG1 and the dummy gate layer DG2 of the dummy gate structure DG in FIG. 4F may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 also be removed by using, for example, etching. After the dummy gate structures DG and the SiGe layers 111 are removed, the active channel sheets 110 are exposed and a plurality of cavities 110c is formed among the active channels 110. In this process, the first spacer 130 has not been re-oxidized (in subsequent FIGS. 4J_a to 4J_b), and thus the first spacers 130 still retains its original etch resistance (or hardness) to resist the etching for the SiGe layers 111 and the wet clean for sidewalls of the first spacer 130.

As illustrated in FIGS. 4H_a to 4H_b, the dielectric layers 135′ are formed in/on the active channels 110 by using, for example, deposition. The dielectric layers 135′ include the first dielectric layer 135A′ and a plurality of the second dielectric layers 135B′, wherein the second dielectric layers 135B′ are located below the first dielectric layer 135A′. In this process, the first dielectric layer 135A′ includes the upper dielectric portion 135A1, the lower dielectric portion 135A2 and the lateral dielectric portion 135A3 which are connected with each other, wherein the lower dielectric portion 135A2 has a thickness substantially equal to that of the upper dielectric portion 135A1 and that of the lower dielectric portion 135A2. Similarly, the second dielectric layer 135B includes the upper dielectric portion 135B1, the lower dielectric portion 135B2 and a lateral dielectric portion 135B3 which are connected with each other, wherein the lateral dielectric portion 135B3 has a thickness substantially equal to that of the upper dielectric portion 135B1 and that of the lower dielectric portion 135B2. In addition, due to the second dielectric layer 135B′ and the first dielectric layer 135A′ being formed in the same deposition process, the second dielectric layer 135B′ may form a thickness substantially equal to that of the first dielectric layer 135A′.

Then, the high-k gate dielectric layer 140 over the inner spacer 120, the first spacers 130, the dielectric layers 135′, the contact etching stop layers 155 and the interlayer dielectric 170 is formed by using, for example, deposition. A high-k gate dielectric layer 140A of the high-k gate dielectric layers 140 disposed on the first dielectric layers 135A′, and a high-k gate dielectric layer 140B of the high-k gate dielectric layers 140 disposed on the corresponding second dielectric layer 135B′. In addition, the high-k gate dielectric layer 140 may be formed in the same process, for example, deposition, such as ALD, CVD, metal-organic CVD, PVD, or a combination thereof.

As illustrated in FIGS. 4I_a to 4I_b, a filler F1 within the cavities 110c and over the first dielectric layer 135A′ is formed by, for example, deposition. The filler F1 may be formed of, for example, aluminium oxide (Al₂O₃).

As illustrated in FIGS. 4J_a to 4J_b, the structure of FIGS. 4I_a and 4I_b may be re-oxidized by using, for example, plasma, plasma ashing, etc. Furthermore, after re-oxidation, the oxygen concentration of the first spacers 130 may be increased. The re-oxidation reduces the etch resistance (or hardness) of the first spacers 130. However, due to the re-oxidation being performed after the removal (for example, etching) of the SiGe layers 111, the etching for the SiGe layers 111 does not affect the first spacers 130 (due to the first spacers 130 still retaining its original etch resistance (or hardness) before the re-oxidation).

For the nanosheet scheme, the first spacer (or poly spacer, or gate spacer) decides most of the parasitic capacitance at FEOL (front-end-of-line) and MEOL (middle end of line). Besides, the deposition of channel high-k material may also inevitably deposit on the surface of spacer, increasing the parasitic capacitance and degrading the switching speed of the device. Therefore, further lowering k-value (for example, by re-oxidation process) of first spacer to recover this penalty is important and desired. In an embodiment, before the re-oxidation process, the k-value (dielectric constant) of the first spacer 130 is, for example, 4, while the k-value (dielectric constant) of the first spacer 130 is increased to, for example, 4.6 after the re-oxidation process. In addition, after the re-oxidation process, the oxygen concentration of the first spacer 130 may be increased by at least, for example, 5%.

During the plasma process, the oxygen/oxidation may diffuse/occur to the active channels 110 and the dielectric layers 135 along (or through) the first spacer 130 and the high-k gate dielectric layers 140. Furthermore, during plasma process, the upper dielectric portion 135A1 and the lateral dielectric portion 135A3 of the first dielectric layer 135A′, an upper portion of the topmost active channel 110A which overlaps the first spacer 130 and the lateral dielectric portion 135B3 of the second dielectric layer 135B may be re-oxidized by the plasma and thus are thickened to form the first oxide layer 137A and the second oxide layers 137B as illustrated in FIGS. 4J_a and 4J_b. During the plasma process, the lower dielectric portion 135A2 (that is, the first dielectric layer 135A in FIG. 1_a) and the upper dielectric portion 135B1 and the lower dielectric portion 135B2 of the second dielectric layer 135B in FIGS. 4H_a and 4H_b may be retained since the plasma can't be applied to the these portions (due to the occlusion of the filler F1).

As illustrated in FIGS. 4K_a to 4K_b, the filler F1 is removed to expose the cavities 110c by using, for example, etching.

As illustrated in FIGS. 4L_a to 4L_b, the metal gate 115 over the high-k gate dielectric layers 140 and the first oxide layer 137A is formed by a process such as ALD, CVD, PVD, remote plasma CVD (RPCVD), plasma enhanced CVD (PECVD), metal-organic CVD (MOCVD), sputtering, electroplating, other suitable processes, or the like. Then, the metal gate 115, the first spacers 130 and the high-k gate dielectric layers 140 may be planarized by, for example, CMP.

As illustrated in FIG. 4M, a hole 170a extending to the source/drain layer 150 is formed in the interlayer dielectric 170 in FIG. 4L_a by using, for example, photolithography, etching, etc. Then, the silicide layer 145 over the exposed source/drain layer 150 are formed by using, for example, deposition. The silicide layer 145 may be a metal or metal alloy silicide, and the metal includes a noble metal, a refractory metal, a rare earth metal, alloys thereof, or combinations thereof. For n-channel FET, the silicide layer 145 may include one or more of TiSi, CrSi, TaSi, MoSi, ZrSi, HfSi, ScSi, Ysi, HoSi, TbSI, GdSi, LuSi, DySi, ErSi, Yb Si or a combination thereof. For p-channel FET, the silicide layer 145 may include one or more of NiSi, CoSi, MnSi, Wsi, Fe Si, RhSi, PdSi, RuSi, PtSi, IrSi, OsSi or a combination thereof.

Then, the contacts 160 in FIG. 1_a are formed over the silicide layer 145 in FIG. 4M to form at least one semiconductor structure 100 as illustrated in FIGS. 1_a and 1_b. The contacts 160 may be formed of a metal including the material the same as or similar to that of the metal gate 115.

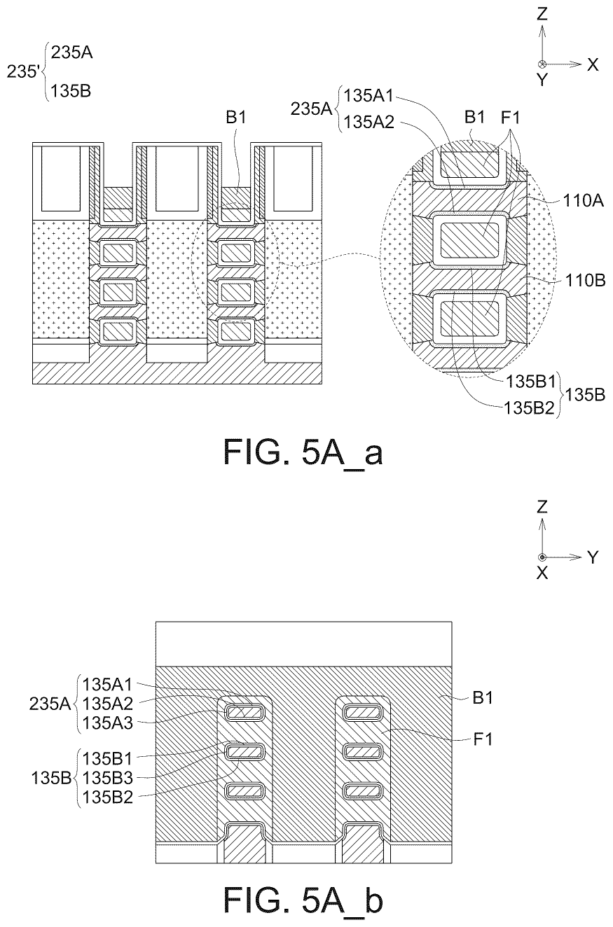

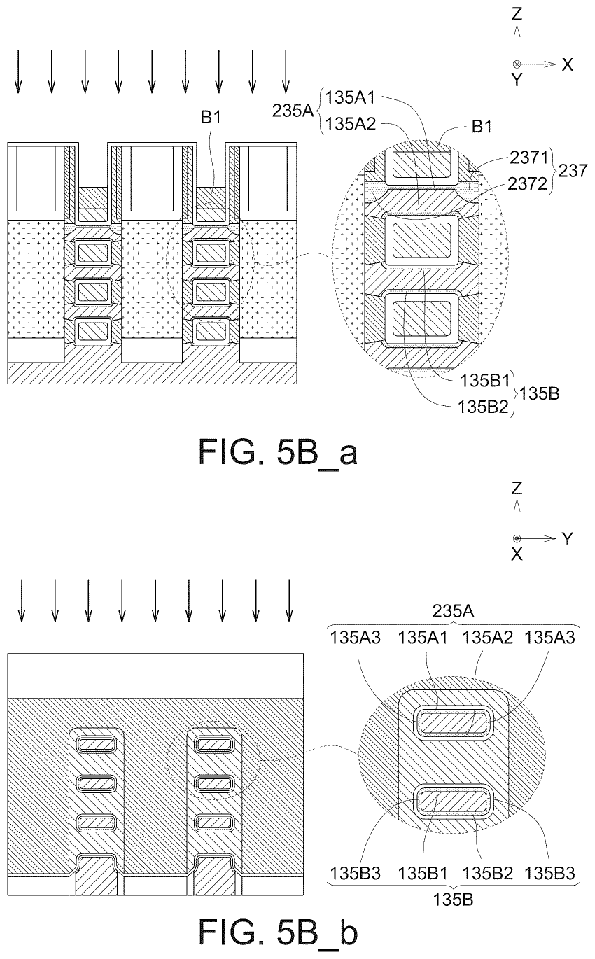

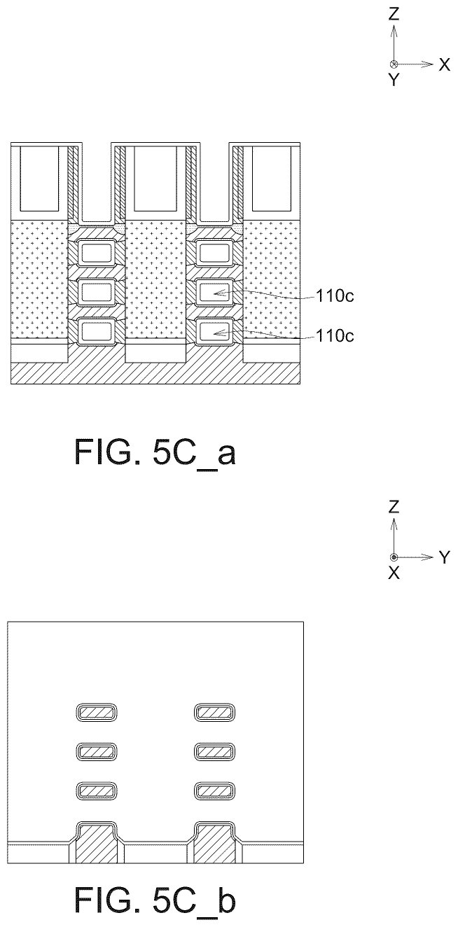

FIGS. 5A_a to 5C_b illustrate schematic diagrams of manufacturing processes of the semiconductor structure 200 in FIGS. 2_a and 2_b.

As illustrated in FIGS. 5A_a to 5A_b, a plurality of blocking layers B1 over the fillers F1 is formed by using, for example, deposition. The blocking layer B1 may be a BARC (Bottom Anti-Reflection Coating).

In FIGS. 5A_a to 5A_b, the dielectric layers 235′ are formed in/on the active channels 110 by using, for example, deposition. The dielectric layers 235′ includes the first dielectric layer 235A and a plurality of the second dielectric layers 135B, wherein the second dielectric layers 135B are located below the first dielectric layer 235A. In this process, the first dielectric layer 235A includes the upper dielectric portion 135A1, the lower dielectric portion 135A2 and the lateral dielectric portion 135A3 which are connected with each other, wherein the lower dielectric portion 135A2 has a thickness substantially equal to that of the upper dielectric portion 135A1 and that of the lower dielectric portion 135A2. Similarly, the second dielectric layer 135B includes the upper dielectric portion 135B1, the lower dielectric portion 135B2 and a lateral dielectric portion 135B3 which are connected with each other, wherein the lateral dielectric portion 135B3 has a thickness substantially equal to that of the upper dielectric portion 135B1 and that of the lower dielectric portion 135B2. In addition, due to the second dielectric layer 135B and the first dielectric layer 235A being formed in the same deposition process, the second dielectric layer 135B may form a thickness substantially equal to that of the first dielectric layer 235A.

As illustrated in FIGS. 5B_a to 5B_b, the structure of FIGS. 5A_a and 5A_b may be re-oxidized by using, for example, plasma, plasma ashing, etc. Furthermore, after re-oxidation, the oxygen concentration of the first spacers 130 may be increased. The re-oxidation may reduce the etch resistance of the first spacers 130. However, due to the re-oxidation being performed after the removal (for example, etching) of the SiGe layers 111, the etching for the SiGe layers 111 does not affect the first spacers 130 (due to the first spacers 130 still retaining its original etch resistance before the re-oxidation).

During the plasma process, the oxygen/oxidation may diffuse/occur along the first spacer 130 to the topmost active channels 110A and the dielectric layers 235A. Furthermore, during the plasma process, an upper portion of the topmost active channel 110A and the dielectric layers 235A which overlap the first spacer 130 in Z-axis may be re-oxidized by the plasma and thus are thickened to form the first oxide layer 237 as illustrated in FIGS. 5B_a and 5B_b. In addition, during the plasma process, the upper dielectric portion 135A1 of the first dielectric layer 235A in FIGS. 5A_a and 5A_b may be retained since the plasma can't be applied to the upper dielectric portion 135A1 (due to the occlusion of the blocking layer B1). In addition, during the plasma process, the lower dielectric portion 135A2 and the lateral dielectric portion 135A3 of the first dielectric layer 235A and the upper dielectric portion 135B1, the lower dielectric portion 135B2 and the lateral dielectric portion 135B3 of the second dielectric layer 135B in FIGS. 5A_a and 5A_b may be retained since the plasma can't be applied to the these portions (due to the occlusion of the filler F1).

As illustrated in FIGS. 5C_a to 5C_b, the filler F1 and the blocking layers B1 in FIGS. 5B_a and 5B_b are removed to expose the cavities 110c by using, for example, etching.

The other processes of the manufacturing method of the semiconductor structure 200 are same as or similar to the corresponding process of the manufacturing method of the semiconductor structure 100, and will not be repeated here.

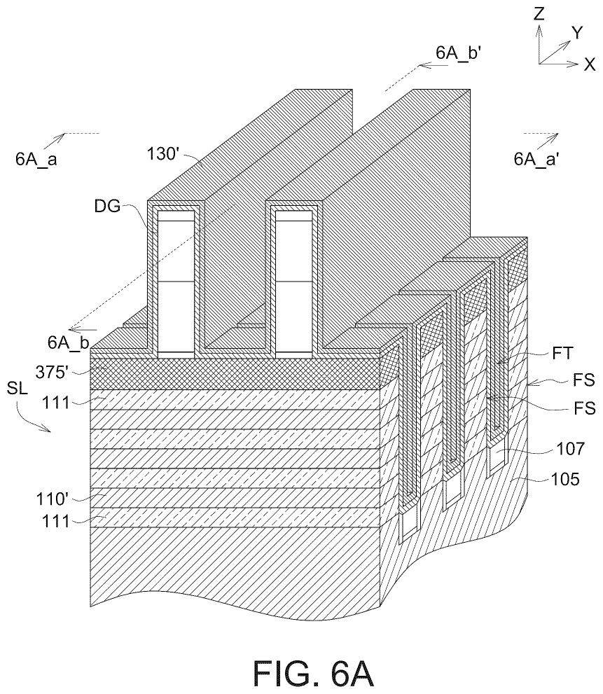

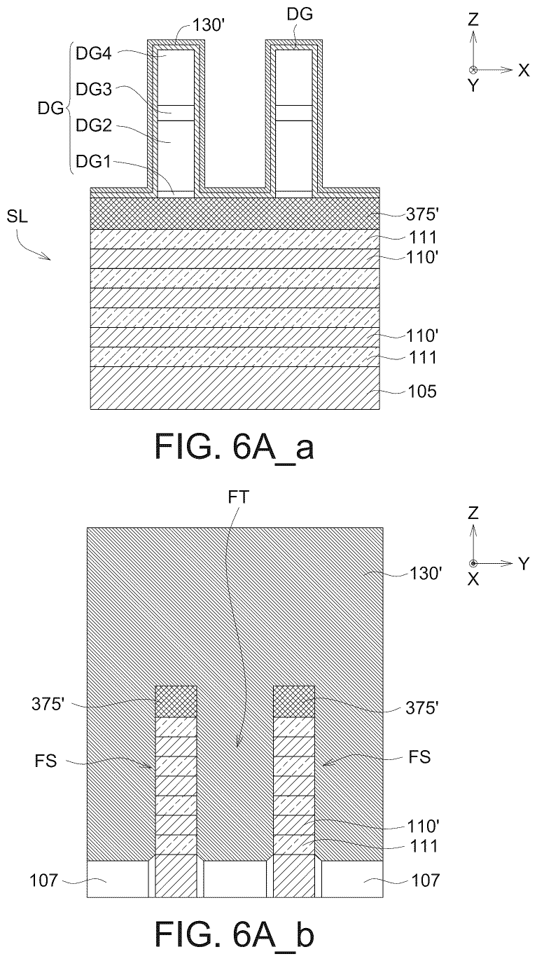

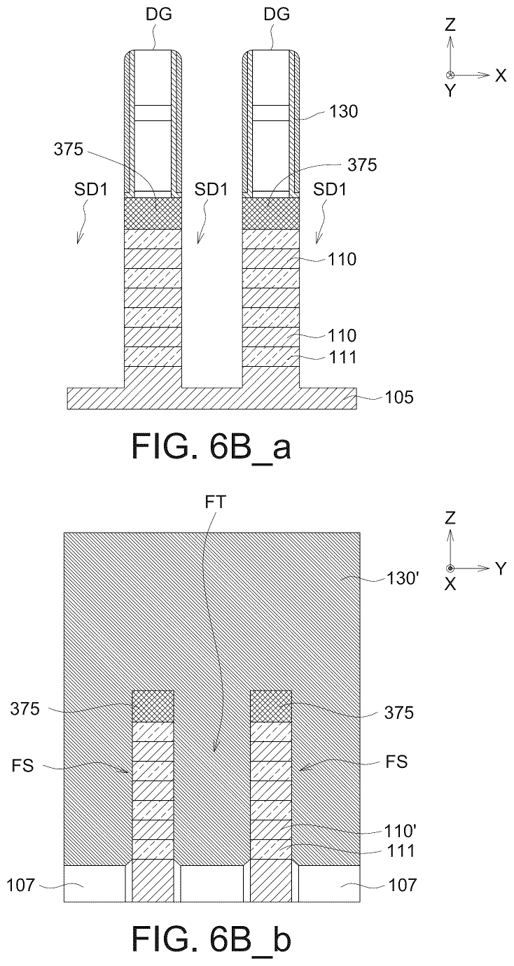

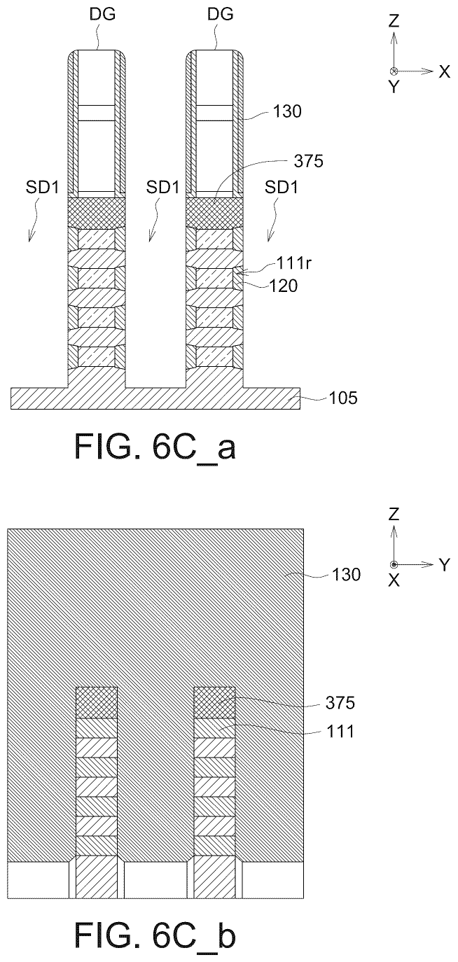

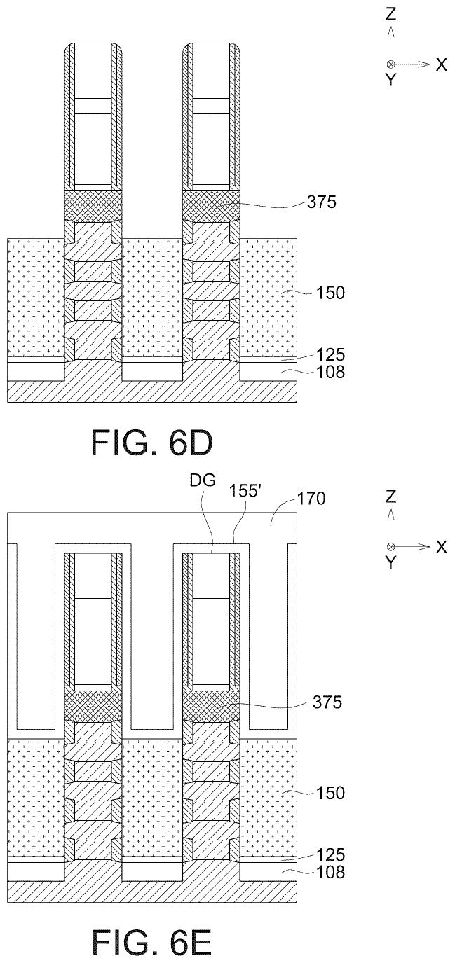

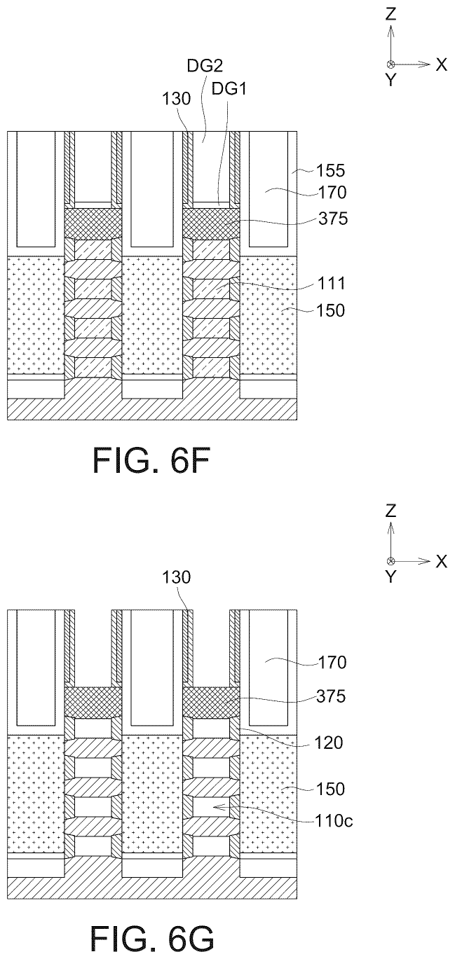

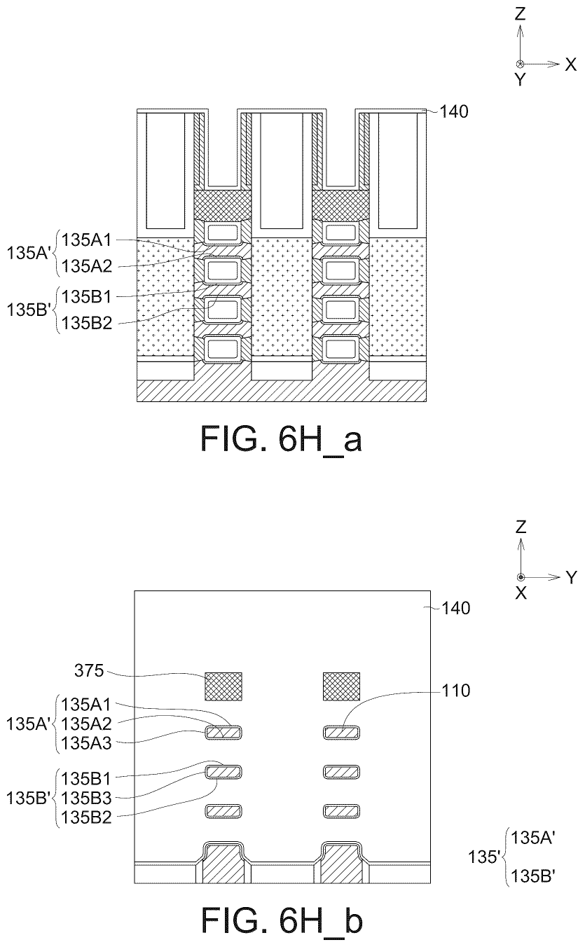

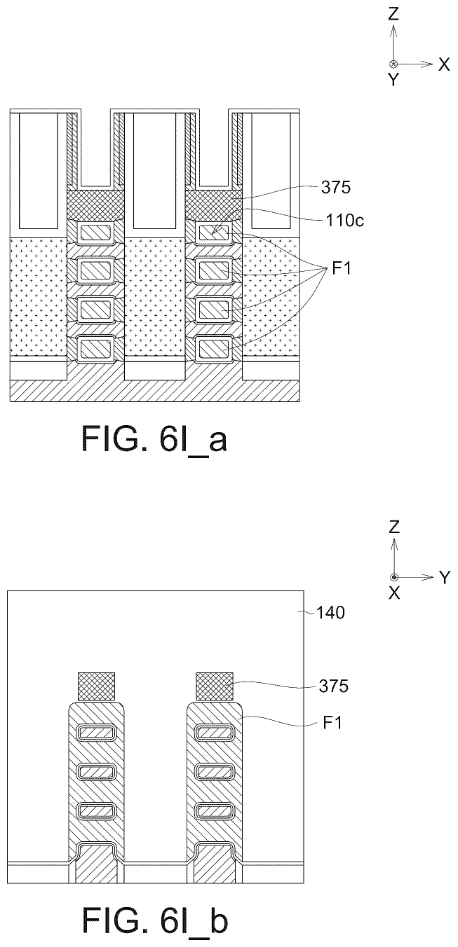

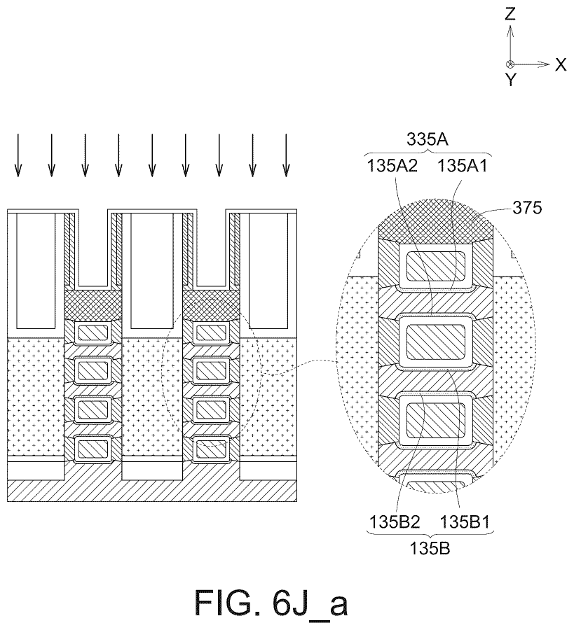

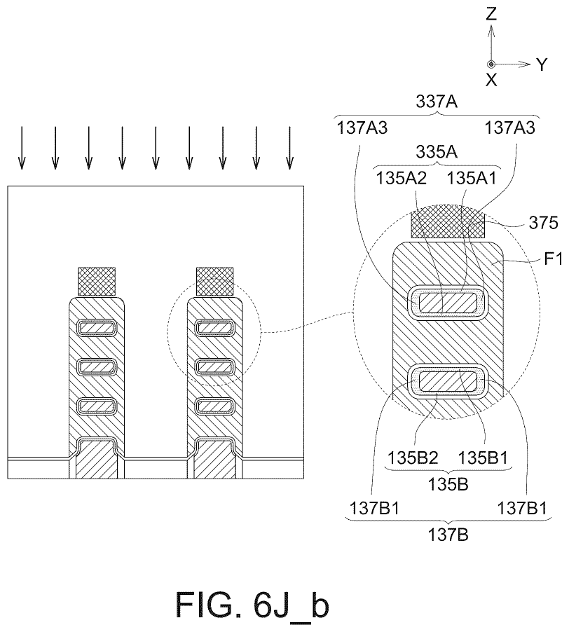

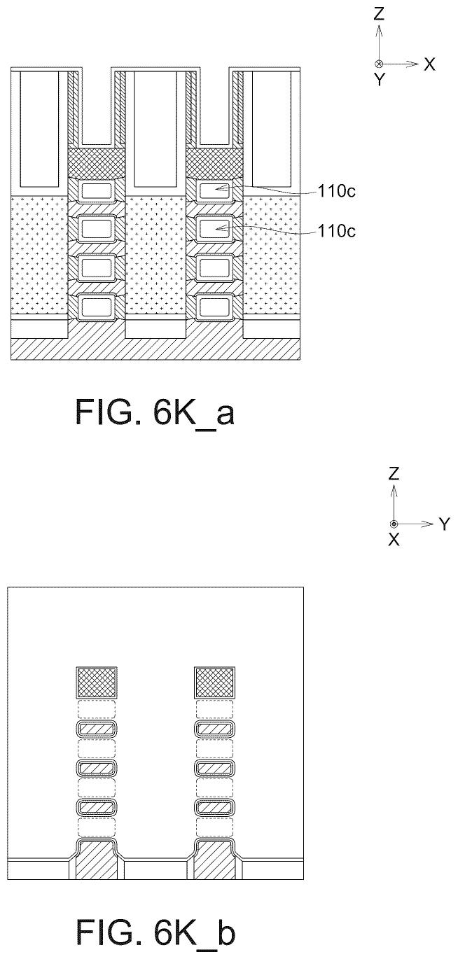

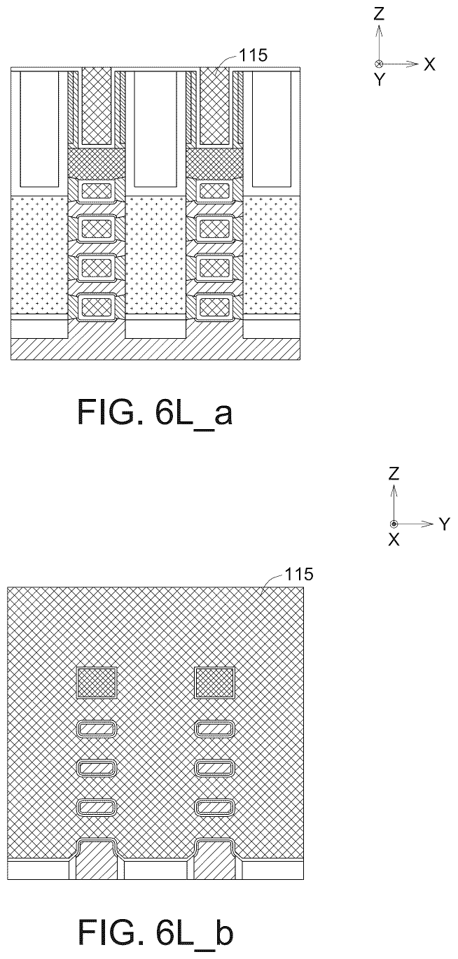

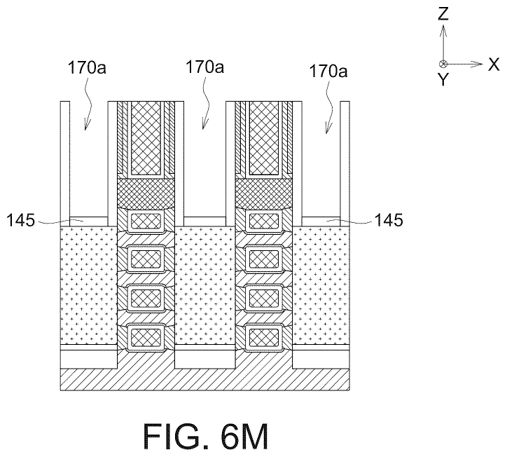

FIGS. 6A to 6M illustrate schematic diagrams of manufacturing processes of the semiconductor structure 300 in FIGS. 3_a and 3_b.

As illustrated in FIGS. 6A, 6A_a and 6A_b, a superlattice structure SL including a plurality of the SiGe layers 111 and a plurality of the silicon layers 110′ is formed on the substrate 105 by epitaxy process, for example, molecular beam epitaxy (MBE), metalorganic chemical vapor deposition (MOCVD) or other suitable epitaxial growth processes. One of the silicon germanium layers 111 is disposed between adjacent two of the silicon layers 110′. The substrate 105 is, for example, silicon wafer. The hard mask may be formed over the superlattice structure SL by for example, deposition, etc. For example, the hard mask may be formed over the topmost SiGe layer 111. Then, the superlattice structure SL and the hard mask may be patterned by using, for example, photolithography, etching, etc. After patterned, the superlattice structure SL form a plurality of fin structures (or referred to as “OD (oxide diffusion)”) FS, and the hard mask forms a plurality of hard mask strip 375′. After patterned, each fin structure FS includes the patterned SiGe layers 111 and silicon layers 110′, and the fin trench FT is formed adjacent two of the fin structures FS.

Then, the oxide layer 107 may be formed in the bottom portion of the fin trench FT between adjacent two of the fin structures FS. The oxide layer 107 may be formed of a material including silicon oxide, silicon nitride, silicon carbide, FSG (fluorosilicate glass), low dielectric constant material or other suitable dielectric material. The dielectric material may be formed in the fin trench FT between adjacent two of the fin structures FS by using, for example, deposition such as hot growth, CVD (Chemical Vapor Deposition), HDP-CVD (High-density plasma CVD), PVD (Physical Vapor Deposition), ALD (Atomic Layer Deposition) and/or spin coating. Then, the dielectric material is planarized by, for example, a CMP (Chemical-Mechanical Planarization) to expose the topmost silicon layer 110′. Then, a portion of the dielectric material is removed by, for example, dry etching, wet etching, RIE (Reactive-Ion Etching) or other etching process, and the remaining portion of the dielectric material forms the oxide layers 107. The oxide layer 107 is referred to as, for example, a STI (Shallow Trench Isolation).

Then, as illustrated in FIGS. 6A_a and 6_b, a plurality of dummy gate structures DG is formed on the fin structures FS and within the fin trenches FT for defining the region of the active channel, and then the first spacer material 130′ over the dummy gate structures DG and the patterned superlattice structure SL is formed.

The dummy gate structure DG includes a dummy dielectric layer DG1, a dummy gate layer DG2, a mask layer DG3 and an oxide layer DG4. The dummy dielectric layer DG1 is formed on the fin structures FS. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

The first spacer material 130′ may be formed of a material including, for example, SiO, SiN, SiOC, SiON, SiOCN, etc. The first spacer material 130′ may be single-layered structure or a multi-layered structure. For multi-layered structure, the first spacer material 130′ may include a first-sub spacer portion and a second-sub spacer portion, wherein the second-sub spacer portion is disposed between the dummy gate structures DG and the first-sub spacer portion. In an embodiment, the first-sub spacer portion may be formed of a material different from that of the second-sub spacer portion. The first-sub spacer portion may be formed of one of SiO, SiN, SiOC, SiON, SiOCN, etc., the second-sub spacer portion may be formed of another of SiO, SiN, SiOC, SiON, SiOCN, etc. In addition, the first spacer material 130′ may be formed by using, for example, SACVD (Sub-Atmospheric CVD), FCCVD (Flowable CVD), ALD, PVD or other suitable process.

As illustrated in FIGS. 6B_a and 6B_b, a portion of the fin structure FS which is not covered by the dummy gate structure DG is removed to form a plurality of source/drain trenches SD1 and a portion of the first spacer material 130′ is removed by etching such as dry etching, wet etching, RIE or other suitable etching process. In addition, the etching process may use bromine-containing etchants (HBr and/or CHBr₃), fluorine-containing etchants (CF₄, SF₆, CH₂F₂, CHF₃ and/or C₂F₆) or other suitable etchant. After etching, the remaining portion of the fin structure FS form a plurality of the active channels 110 and a plurality of the SiGe layers 111 which arranged alternately, and the remaining portion of the hard mask strip 375′ forms a plurality of the blocking layers 375 over the topmost SiGe layers 111. After etching, the remaining portion of the first spacer material 130′ forms a plurality of the first spacers 130 which are disposed over the remaining portion of the fin structure FS, for example, the topmost active channels 110.

As illustrated in FIGS. 6C_a and 6C_b, a, two recesses 111r are formed in adjacent two ends of the corresponding SiGe layer 111 by using, for example, wet etching. The wet etching may selectively etches the SiGe layer 111, and the wet etchant includes, but not limited to, ammonium hydroxide (NH₄OH), tetramethylammonium hydroxide (TMAH), ethylenediamine ptrocatechol (EDP) and potassium hydroxide (KOH).

Then, a plurality of the inner spacers 120 are formed in the recesses 111r. In an embodiment, an inner spacer material over the first spacers 130, the active channel 110, the recesses 111r, sidewalls of the source/drain trenches SD1 is formed by using, for example, deposition. The inner spacer material is formed of a material including silicon oxide, silicon nitride, silicon carbide, silicon carbon nitride, silicon carbon nitride, silicon carbon oxynitride or other suitable material. Then, a portion of the inner spacer material is removed by using, for example, ALD, etc. The remaining portion of the inner spacer material forms a plurality of the inner spacers 120.

As illustrated in FIG. 6D, the separation layers 108 may be formed on a bottom of the source/drain trenches SD1. In an embodiment, the separation layers 108 may be a semiconductor layer, for example, silicon germanium layer, and the separation layers 108 may be formed by MBE, CVD, MOCVD, etc. Then, the isolation layer 125 over the separation layers 108 is formed by using, for example, deposition, exposure, etching, development, etc. Then, a plurality of the source/drain layers 150 over the isolation layer 125 may be formed within the source/drain trenches SD1.

The source/drain layer 150 may be formed using an epitaxial process, such as VPE, UHV-CVD, MBE, and/or other suitable processes. Example n-type source/drain layer may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain layer may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process).

As illustrated in FIG. 6E, a CESL material 155′ over the first spacers 130, the source/drain layers 150 and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like. Then, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIG. 6F, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the first spacer 130 and the ILD 170 may form, for example, a planarized surface.

As illustrated in FIG. 6G, the SiGe layers 111 and the dummy dielectric layer DG1 and the dummy gate layer DG2 of the dummy gate structure DG in FIG. 6F may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 also be removed by using, for example, etching. After the dummy gate structures DG and the SiGe layers 111 are removed, the active channel sheets 110 are exposed and a plurality of cavities 110c is formed among the active channels 110. In this process, the first spacer 130 has not been re-oxidized (in subsequent FIGS. 6J_a to 6J_b), and thus the first spacers 130 still retains its original etch resistance (or hardness) to resist the etching for the SiGe layers 111 and the wet clean for sidewalls of the first spacer 130.

As illustrated in FIGS. 6H_a to 6H_b, the dielectric layers 135′ are formed in/on the active channels 110 by using, for example, deposition. The first dielectric layers 135′ include the first dielectric layer 135A′ and a plurality of the first dielectric layers 135B′, wherein the first dielectric layers 135B′ are located below the first dielectric layer 135A′. In this process, the first dielectric layer 135A′ includes the upper dielectric portion 135A1, the lower dielectric portion 135A2 and the lateral dielectric portion 135A3 which are connected with each other, wherein the lower dielectric portion 135A2 has a thickness substantially equal to that of the upper dielectric portion 135A1 and that of the lower dielectric portion 135A2. Similarly, the first dielectric layer 135B includes the upper dielectric portion 135B1, the lower dielectric portion 135B2 and a lateral dielectric portion 135B3 which are connected with each other, wherein the lateral dielectric portion 135B3 has a thickness substantially equal to that of the upper dielectric portion 135B1 and that of the lower dielectric portion 135B2. In addition, due to the first dielectric layer 135B′ and the first dielectric layer 135A′ being formed in the same deposition process, the first dielectric layer 135B′ may form a thickness substantially equal to that of the first dielectric layer 135A′.

Then, the high-k gate dielectric layer 140 over the inner spacer 120, the first spacers 130, the first dielectric layers 135′, the contact etching stop layers 155 and the interlayer dielectric 170 is formed by using, for example, deposition. A high-k gate dielectric layer 140A of the high-k gate dielectric layers 140 disposed on the first dielectric layers 135A′, and a high-k gate dielectric layer 140B of the high-k gate dielectric layers 140 disposed on the corresponding first dielectric layer 135B′. In addition, the high-k gate dielectric layer 140 may be formed in the same process, for example, deposition, such as ALD, CVD, metal-organic CVD, PVD, or a combination thereof.

As illustrated in FIGS. 6I_a to 6I_b, the filler F1 within the cavities 110c and over the first dielectric layer 135A′ is formed by, for example, deposition. The filler F1 may be formed of a material the same as or similar to that of the first spacer 130. The filler F1 covers an upper surface, a lower surface and a lateral surface of each active channel 110.

As illustrated in FIGS. 6J_a to 6J_b, the structure of FIGS. 6I_a and 6I_b may be re-oxidized by using, for example, plasma, plasma ashing, etc. Furthermore, after re-oxidation, the oxygen concentration of the first spacers 130 may be increased. The re-oxidation reduces the etch resistance (or hardness) of the first spacers 130. However, due to the re-oxidation being performed after the removal (for example, etching) of the SiGe layers 111, the etching for the SiGe layers 111 does not affect the first spacers 130 (due to the first spacers 130 still retaining its original etch resistance (or hardness) before the re-oxidation).

During the plasma process, the oxygen/oxidation may diffuse/occur to the active channels 110 and the dielectric layers 135 along (or through) the first spacer 130 and the high-k gate dielectric layers 140. During the plasma process, the lateral dielectric portion 135A3 of the first dielectric layer 135A′ may be re-oxidized by the plasma and thus are thickened to form the first oxide layer 337A as illustrated in FIG. 6J_b. During the plasma process, the upper dielectric portion 135A1 and the lower dielectric portion 135A2 of the first dielectric layer 135A′ in FIG. 6H_b may be retained since the plasma can't be applied to these portions (due to the occlusion of the blocking layers 375). During the plasma process, the upper dielectric portion 135B1 and the lower dielectric portion 135B2 of the second dielectric layer 135B′ in FIG. 6H_b may be retained since the plasma cannot be applied to these portions (due to the occlusion of the filler F1).

As illustrated in FIGS. 6K_a to 6K_b, the filler F1 is removed to expose the cavities 110c by using, for example, etching.

As illustrated in FIGS. 6L_a to 6L_b, the metal gate 115 over the high-k gate dielectric layers 140 and the first oxide layer 137A is formed by a process such as ALD, CVD, PVD, remote plasma CVD (RPCVD), plasma enhanced CVD (PECVD), metal-organic CVD (MOCVD), sputtering, electroplating, other suitable processes, or the like. Then, the metal gate 115, the first spacers 130 and the high-k gate dielectric layers 140 may be planarized by, for example, CMP.

As illustrated in FIG. 6M, a hole 170a extending to the source/drain layer 150 formed in the interlayer dielectric 170 in FIG. 6L_a by using, for example, photolithography, etching, etc. Then, the silicide layer 145 over the exposed source/drain layer 150 is formed by using, for example, deposition.

Then, the contacts 160 in FIG. 3_a are formed over the silicide layer 145 in FIG. 6M to form at least one semiconductor structure 300 as illustrated in FIGS. 3_a and 3_b. The contacts 160 may be formed of a metal including the material the same as or similar to that of the metal gate 115.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a plurality of active channels, a dielectric layer in the topmost active channel and an oxide layer in the topmost active channel. The oxide layer has a thickness greater than that of the dielectric layer. In an embodiment, after a plurality of SiGe layers of a superlattice structure is removed, a first spacer over the active channels may be re-oxidized by, for example, plasma. As a result, the etching for the SiGe layers does not affect the first spacers (due to the first spacers still retaining its original etch resistance (or hardness) before the re-oxidation).

Example embodiment 1: a semiconductor structure comprises a substrate, a plurality of active channels vertically stacked to each other, a first dielectric layer in the topmost active channel, and a first oxide layer in the topmost active channel and includes a first lateral oxide portion connected with the first dielectric layer. The first lateral oxide portion has a thickness greater than that of the first dielectric layer.

Example embodiment 2 based on Example embodiment 1: the first lateral oxide portion has the thickness greater than that of the first dielectric layer.

Example embodiment 3 based on Example embodiment 1: each active channel extends in a first direction, the first dielectric layer is disposed in a lower portion of the topmost active channel, and the first lateral oxide portion has the thickness in a second direction greater than that of the first dielectric layer in the second direction.

Example embodiment 4 based on Example embodiment 1: the first oxide layer further includes a first upper oxide portion in an upper portion of the topmost active channel, and the first upper oxide portion has a thickness greater than that of the first dielectric layer.

Example embodiment 5 based on Example embodiment 3: the first lateral oxide portion has the thickness greater than the thickness of the first upper oxide portion.

Example embodiment 6 based on Example embodiment 1: the semiconductor structure further includes a metal gate having a lateral surface, and a first spacer on the lateral surface of the metal gate. The first spacer is located above the first lateral oxide portion of the first oxide layer.

Example embodiment 7 based on Example embodiment 6: the first lateral oxide portion overlap the first spacer.

Example embodiment 8 based on Example embodiment 1: the first oxide layer further includes a second lateral oxide portion connected with the first dielectric layer; and a second upper oxide portion connected with the second lateral oxide portion. The second upper oxide portion has a thickness greater than that of the second lateral oxide portion.

Example embodiment 9 based on Example embodiment 1: the semiconductor structure further incudes a second oxide layer disposed in the active channel which is located below the topmost active channel; and a second dielectric layer disposed in the active channel which is located below the topmost active channel. The second oxide layer has a thickness greater than that of the second dielectric layer.

Example embodiment 10: a semiconductor structure includes a substrate, a plurality of active channels vertically stacked to each other, a blocking layer above the topmost active channel, a first dielectric layer in the topmost active channel, and a first oxide layer in the topmost active channel. The first oxide layer includes a lateral oxide portion connected with the first dielectric layer. The lateral oxide portion has a thickness greater than that of the first dielectric layer.

Example embodiment 11 based on Example embodiment 10: the semiconductor structure further includes a metal gate above the active channels. The lateral oxide portion overlaps the metal gate.

Example embodiment 12 based on Example embodiment 10: the semiconductor structure further includes a second oxide layer in the active channel which is located below the topmost active channel, and a second dielectric layer disposed in the active channel which is located below the topmost active channel. The second oxide layer has a thickness greater than that of the second dielectric layer.

Example embodiment 13 based on Example embodiment 10: the blocking layer is a hard mask.

Example embodiment 14 based on Example embodiment 10: the semiconductor structure further includes a high-k gate dielectric layer surrounding the blocking layer.

Example embodiment 15 based on Example embodiment 10: the semiconductor structure further includes a metal gate having a lateral surface, and a first spacer on the lateral surface of the metal gate. The first spacer is located above the first lateral oxide portion of the first oxide layer.

Example embodiment 16 based on Example embodiment 15: the blocking layer is disposed between the first spacer and the topmost active channel.

Example embodiment 17: a manufacturing method for a semiconductor structure, including the following steps: forming a plurality of active channels on a substrate; forming a first spacer on the active channels; forming a first dielectric layer in the topmost active channel; and applying a plasma to the first spacer and the topmost active channel to re-oxidize the first spacer and form a first oxide layer in the topmost active channel, wherein a first lateral oxide portion of the first oxide layer is connected with the first dielectric layer, and the first lateral oxide portion has a thickness greater than that of the first dielectric layer.

Example embodiment 18 based on Example embodiment 17: the manufacturing method further includes: forming a superlattice structure including a plurality of silicon germanium (SiGe) layers and a plurality of silicon layers which arranged alternately; removing the SiGe layers to form a plurality of cavities; and before applying the plasma to the first spacer and the topmost active channel to re-oxidize the first spacer and form the first oxide layer in the topmost active channel, forming a filler within the cavities and over the first dielectric layer.

Example embodiment 19 based on Example embodiment 18: the manufacturing method further includes: forming a blocking layer over the filler.

Example embodiment 20 based on Example embodiment 19: in forming the filler within the cavities and over the first dielectric layer, the filler covers an upper surface and a lateral surface of each active channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a plurality of active channels vertically stacked to each other;
a first dielectric layer in the topmost active channel; and
a first oxide layer in the topmost active channel, comprising
a first lateral oxide portion connected with the first dielectric layer;
wherein the first lateral oxide portion has a thickness greater than that of the first dielectric layer.

2. The semiconductor structure according to claim 1, wherein the first lateral oxide portion has the thickness greater than that of the first dielectric layer.

3. The semiconductor structure according to claim 1, wherein each active channel extends in a first direction, the first dielectric layer is disposed in a lower portion of the topmost active channel, and the first lateral oxide portion has the thickness in a second direction greater than that of the first dielectric layer in the second direction.

4. The semiconductor structure according to claim 1, wherein the first oxide layer further comprises:
a first upper oxide portion in an upper portion of the topmost active channel and having a thickness greater than that of the first dielectric layer.

5. The semiconductor structure according to claim 3, wherein the first lateral oxide portion has the thickness greater than the thickness of the first upper oxide portion.

6. The semiconductor structure according to claim 1, further comprising:
a metal gate having a lateral surface; and
a first spacer on the lateral surface of the metal gate;
wherein the first spacer is located above the first lateral oxide portion of the first oxide layer.

7. The semiconductor structure according to claim 6, wherein the first lateral oxide portion overlap the first spacer.

8. The semiconductor structure according to claim 1, wherein the first oxide layer further comprises:
a second lateral oxide portion connected with the first dielectric layer; and
a second upper oxide portion connected with the second lateral oxide portion;
wherein the second upper oxide portion has a thickness greater than that of the second lateral oxide portion.

9. The semiconductor structure according to claim 1, further comprising:
a second oxide layer disposed in the active channel which is located below the topmost active channel; and
a second dielectric layer disposed in the active channel which is located below the topmost active channel;
wherein the second oxide layer has a thickness greater than that of the second dielectric layer.

10. A semiconductor structure, comprising:
a substrate;
a plurality of active channels vertically stacked to each other;
a blocking layer above the topmost active channel;
a first dielectric layer in the topmost active channel; and
a first oxide layer in the topmost active channel, comprising:
a lateral oxide portion connected with the first dielectric layer;
wherein the lateral oxide portion has a thickness greater than that of the first dielectric layer.

11. The semiconductor structure according to claim 10, further comprising:
a metal gate above the active channels;
wherein the lateral oxide portion overlaps the metal gate.

12. The semiconductor structure according to claim 10, further comprises:
a second oxide layer in the active channel which is located below the topmost active channel;
a second dielectric layer disposed in the active channel which is located below the topmost active channel;
wherein the second oxide layer has a thickness greater than that of the second dielectric layer.

13. The semiconductor structure according to claim 10, wherein the blocking layer is a hard mask.

14. The semiconductor structure according to claim 10, further comprising:
a high-k gate dielectric layer surrounding the blocking layer.

15. The semiconductor structure according to claim 10, further comprising:
a metal gate having a lateral surface; and
a first spacer on the lateral surface of the metal gate;
wherein the first spacer is located above the first lateral oxide portion of the first oxide layer.

16. The semiconductor structure according to claim 15, wherein the blocking layer is disposed between the first spacer and the topmost active channel.

17. A manufacturing method for a semiconductor structure, comprising:
forming a plurality of active channels on a substrate;
forming a first spacer on the active channels;
forming a first dielectric layer in the topmost active channel; and
applying a plasma to the first spacer and the topmost active channel to re-oxidize the first spacer and form a first oxide layer in the topmost active channel, wherein a first lateral oxide portion of the first oxide layer is connected with the first dielectric layer, and the first lateral oxide portion has a thickness greater than that of the first dielectric layer.

18. The manufacturing method according to claim 17, further comprising:
forming a superlattice structure including a plurality of silicon germanium (SiGe) layers and a plurality of silicon layers which arranged alternately;
removing the SiGe layers to form a plurality of cavities; and
before applying the plasma to the first spacer and the topmost active channel to re-oxidize the first spacer and form the first oxide layer in the topmost active channel, forming a filler within the cavities and over the first dielectric layer.

19. The manufacturing method according to claim 18, further comprising:
forming a blocking layer over the filler.

20. The manufacturing method according to claim 19, wherein in forming the filler within the cavities and over the first dielectric layer, the filler covers an upper surface and a lateral surface of each active channel.
